(19) United States
(12) Patent Application Publication
(10) Pub. No.: US 2026/0367304 A1
(43) Pub. Date: Nov. 19, 2026

(54) RETARDATION FILM, POLARIZING PLATE, AND IMAGE DISPLAY DEVICE

(71) Applicant: FUJIFILM Corporation, Tokyo (JP)

(72) Inventors: Yuki NAKAMURA, Minamiashigara-shi (JP); Katsufumi OHMURO, Minamiashigara-shi (JP); Tatsuya IWASAKI, Minamiashigara-shi (JP); Shinsuke TOKUOKA, Minamiashigara-shi (JP)

(73) Assignee: FUJIFILM Corporation, Tokyo (JP)

(21) Appl. No.: 19/701,814

(22) Filed: Jun. 9, 2026

Related U.S. Application Data
(63) Continuation of application No. PCT/JP2024/041742, filed on Nov. 26, 2024.

(30) Foreign Application Priority Data
Dec. 27, 2023 (JP) 2023-220525
Apr. 30, 2024 (JP) 2024-073532
Aug. 19, 2024 (JP) 2024-137614

(51) Int. Cl. G02B 5/30; C09K 19/20; C09K 19/34; G02F 1/1335; G02F 1/13363

(52) U.S. Cl. CPC G02B 5/3083; C09K 19/2028; C09K 19/3405; C09K 19/3497; G02F 1/133528; G02F 1/13363; C09K 2019/2035; C09K 2019/3408; C09K 2219/03; C09K 2323/06

(57) ABSTRACT

An object of the present invention is to provide a retardation film with which it is possible to manufacture an image display device in which occurrence of mounting unevenness is suppressed, and a polarizing plate and an image display device using the retardation film. The retardation film according to the present invention is a retardation film including a support having in-plane retardation exhibiting reverse wavelength dispersibility, and a liquid crystal layer directly laminated on the support, in which the support is a polymer film subjected to a stretching treatment in at least one in-plane direction, the liquid crystal layer is a positive C-plate obtained by immobilizing an alignment state of a liquid crystal composition containing a liquid crystal compound, and a photoelastic constant of the support is 30×10⁻¹² Pa or less.

### CROSS-REFERENCE TO RELATED APPLICATIONS

This application is a Continuation of PCT International Application No. PCT/JP2024/041742 filed on Nov. 26, 2024, which claims priority under 35 U.S.C. § 119(a) to Japanese Patent Application No. 2023-220525 filed on Dec. 27, 2023, Japanese Patent Application No. 2024-073532 filed on Apr. 30, 2024, and Japanese Patent Application No. 2024-137614 filed on Aug. 19, 2024. The above applications are hereby expressly incorporated by reference, in their entirety, into the present application.

### BACKGROUND OF THE INVENTION

### 1. Field of the Invention

The present invention relates to a retardation film, a polarizing plate, and an image display device.

### 2. Description of the Related Art

In the related art, a polarizing plate having a retardation film and a polarizer has been used for a liquid crystal display device, an organic electroluminescence device, or the like for the purpose of optical compensation, antireflection, or the like.

As an example of a phase difference film for such a polarizing plate, WO2020-045224 describes retardation film comprising: a support; and a liquid crystal layer formed of a liquid crystal composition containing a liquid crystal compound so as to be in contact with the support, in which a surface energy of a surface of the support on which the liquid crystal layer is formed is 45 mN/m or more and a non-polar dispersion force component included in the surface energy is 45 mN/m or more, the liquid crystal compound is immobilized in an aligned state, and a contrast is more than 10000.” ([claim 1]).

### SUMMARY OF THE INVENTION

The present inventors have conducted studies on the retardation film described in WO2020-045224, and as a result, it has been found that in a case where an image display device produced using the retardation film is observed in a black display state from an oblique direction, light leakage and tint unevenness [hereinafter, these are collectively abbreviated as “mounting unevenness” ] may occur depending on an observation azimuth. As a result, the present inventors clarified that there is a room for improvement.

Therefore, an object of the present invention is to provide a retardation film with which it is possible to produce an image display device in which the occurrence of mounting unevenness is suppressed, and a polarizing plate and an image display device using the retardation film.

As a result of intensive studies on the above-described object, the present inventors have found that an image display device in which the occurrence of mounting unevenness is suppressed can be produced by using a retardation film including a support consisting of a polymer film in which an in-plane retardation exhibits reverse wavelength dispersibility and a photoelastic constant is 30×10⁻¹² Pa or less or a product of the photoelastic constant and a thickness is 2,000×10⁻¹² Pa·μm or less, and a liquid crystal layer (positive C-plate) directly laminated on the support, and have completed the present invention.

That is, the present inventors have found that the above-described object can be achieved by employing the following configurations.
[1]A retardation film comprising: a support in which an in-plane retardation exhibits reverse wavelength dispersibility; and a liquid crystal layer directly laminated on the support, in which
the support is a polymer film subjected to a stretching treatment in at least one in-plane direction,
the liquid crystal layer is a positive C-plate obtained by immobilizing an alignment state of a liquid crystal composition containing a liquid crystal compound, and
a photoelastic constant of the support is 30×10⁻¹² Pa or less.
[2] The retardation film according to [1], in which a difference between a solubility parameter of a polymer contained in the polymer film and a solubility parameter of a liquid crystal compound having a highest content among liquid crystal compounds contained in the liquid crystal composition is 8.8 or more.
[3] The retardation film according to [1] or [2], in which a polymer contained in the polymer film is polycarbonate or polyester.
[4] The retardation film according to any one of [1] to [3], in which the photoelastic constant of the support is 25×10⁻¹² Pa or less.
[5] The retardation film according to any one of [1] to [4], in which a difference between a solubility parameter of a polymer contained in the polymer film and a solubility parameter of a liquid crystal compound having a highest content among liquid crystal compounds contained in the liquid crystal composition is 9.5 or more.
[6] The retardation film according to any one of [1] to [5], in which the support is a positive A-plate.
[7] The retardation film according to any one of [1] to [6], in which a thickness direction retardation of the liquid crystal layer exhibits reverse wavelength dispersibility.
[8] The retardation film according to any one of [1] to [7], in which the liquid crystal composition further contains a boronic acid monomer having a polymerizable group and a boronic acid group represented by Formula (B).
[9] The retardation film according to any one of [1] to [8], in which a polymer contained in the polymer film satisfies Expression (1).
[10]A retardation film comprising: a support in which an in-plane retardation exhibits reverse wavelength dispersibility; and a liquid crystal layer directly laminated on the support, in which
the support is a polymer film subjected to a stretching treatment in at least one in-plane direction,
the liquid crystal layer is a positive C-plate obtained by immobilizing an alignment state of a liquid crystal composition containing a liquid crystal compound, and
a product of a photoelastic constant (unit: Pa) and a thickness (unit: μm) of the support is 2,000×10⁻¹² Pa·μm or less.
[11]A polarizing plate comprising: the retardation film according to any one of [1] to [10]; and a polarizer.
[12] The polarizing plate according to [11], in which an absorption axis of the polarizer and a slow axis of the support included in the retardation film are orthogonal or parallel to each other.
[13] The polarizing plate according to [11], in which an absorption axis of the polarizer and a slow axis of the support included in the retardation film are parallel to each other.
[14] An image display device comprising: the polarizing plate according to any one of [11] to [13].

As described below, according to the present invention, it is possible to provide a retardation film with which an image display device in which the occurrence of mounting unevenness is suppressed can be manufactured, and a polarizing plate and an image display device using the retardation film.

### DESCRIPTION OF THE PREFERRED EMBODIMENTS

Hereinafter, the present invention will be described in detail.

The description of configuration requirements described below may be made based on typical embodiments of the present invention, but the present invention is not limited to such embodiments.

In the present specification, numerical ranges represented by “to” include numerical values before and after “to” as lower limit values and upper limit values.

In addition, in a range of numerical values described in stages in the present specification, the upper limit value or the lower limit value described in a certain range of numerical values may be replaced with an upper limit value or a lower limit value of the range of numerical values described in other stages. In addition, regarding the numerical range described in the present specification, an upper limit value or a lower limit value described in a numerical value may be replaced with a value described in Examples.

In addition, in the present specification, materials that correspond to each component may be used alone or in combination of two or more kinds. Here, in a case where two or more kinds of materials are used in combination for each component, the content of the component refers to the total content of the materials to be combined unless specified otherwise.

In addition, in the present specification, for an angle, “orthogonal” and “parallel” mean a range of an angle of 10°, and for an angle, “same” and “different” can be determined based on whether or not the difference is less than 5°.

In addition, in the present specification, “visible light” refers to 380 to 780 nm. In addition, in the present specification, a measurement wavelength is 550 nm unless otherwise specified.

In addition, in the present specification, a bonding direction of a divalent group (for example, —O—CO—) described is not particularly limited, and for example, in a case where L² in an “L¹-L²-L³” bond is —O—CO—, and a bonding position on the L¹ side is represented by *1 and a bonding position on the L³ side is represented by *2, L² may be *1-O—CO—*2 or *1-CO—O—*2.

Next, terms used in the present specification will be described.

### [Slow Axis]

In the present specification, “slow axis” means a direction in which the in-plane refractive index is maximum. In addition, the slow axis of the retardation film is intended to mean a slow axis of the entire retardation film.

### [Re(λ) and Rth(λ)]

In the present specification, Re (λ) and Rth (λ) each represent an in-plane retardation at a wavelength λ and a retardation at a wavelength λ in a thickness direction. Unless otherwise specified, the wavelength λ refers to 550 nm.

In addition, in the present specification, Re(λ) and Rth(λ) are values measured at a wavelength λ using AxoScan OPMF-1 (manufactured by Optoscience. Inc.).

Specifically, by inputting an average refractive index ((nx+ny+nz)/3) and a film thickness (d (μm)) in AxoScan OPMF-1,
a slow axis direction (°)

Re(λ)=R0(λ)

Rth(λ)=((nx+ny)/2-nz)×d
are calculated.
R0(λ) is expressed in a numerical value calculated with AxoScan OPMF-1, and means Re(λ).

### [Substituent]

In the present specification, examples of a substituent (monovalent substituent) include substituents described in the following substituent group A.

In the present specification, “may have a substituent” includes not only an aspect of not having a substituent but also an aspect of having one or more substituents.

### <Substituent Group A>

Examples of the substituent include:
a halogen atom (for example, a fluorine atom, a chlorine atom, or a bromine atom, preferably a chlorine atom or a fluorine atom, and more preferably a fluorine atom);
an alkyl group (a linear, branched, or cyclic alkyl group having preferably 1 to 48 carbon atoms, more preferably 1 to 24 carbon atoms, and particularly preferably 1 to 8 carbon atoms, such as a linear alkyl group having 1 to 6 carbon atoms (for example, a methyl group, an ethyl group, a n-propyl group, a n-butyl group, a n-pentyl group, and a n-hexyl group), a branched alkyl group having 3 to 6 carbon atoms (for example, an isopropyl group, an isobutyl group, a tert-butyl group, a sec-butyl group, a neopentyl group, an isohexyl group, and a 3-methylpentyl group), and a cyclic alkyl group having 3 to 12 carbon atoms (for example, a cyclopropyl group, a cyclopentyl group, a cyclohexyl group, a 1-norbornyl group, and a 1-adamantyl group));
an alkenyl group (an alkenyl group having preferably 2 to 48 carbon atoms and more preferably 2 to 18 carbon atoms, such as a vinyl group, an allyl group, a 1-butenyl group, and a 2-butenyl group);
an alkynyl group (an alkynyl group having preferably 2 to 6 carbon atoms and more preferably 2 to 4 carbon atoms, such as an ethynyl group, a 1-propynyl group, a propargyl group, a 1-butynyl group, and a 2-butynyl group);
an aryl group (an aryl group having preferably 6 to 48 carbon atoms and more preferably 6 to 24 carbon atoms, such as a phenyl group, an oligoaryl group (a naphthyl group or an anthryl group), a phenanthrenyl group, a fluorenyl group, a pyrenyl group, a triphenylenyl group, and a biphenyl group);
a heteroaryl group (a heterocyclic group having preferably 1 to 32 carbon atoms and more preferably 1 to 18 carbon atoms, such as a 2-thienyl group, a 4-pyridyl group, a 2-furyl group, a 2-pyrimidinyl group, a 1-pyridyl group, a 2-benzothiazolyl group, a 1-imidazolyl group, a 1-pyrazolyl group, and a benzotriazol-1-yl group);
an arylalkyl group (an arylalkyl group having preferably 7 to 15 carbon atoms, such as a benzyl group, a phenethyl group, a methylbenzyl group, a phenylpropyl group, a 1-methylphenylethyl group, a phenylbutyl group, a 2-methylphenylpropyl group, a tetrahydronaphthyl group, a naphthylmethyl group, a naphthylethyl group, an indenyl group, a fluorenyl group, an anthracenylmethyl group (an anthrylmethyl group), and a phenanthrenylmethyl group (a phenanthrylmethyl group));
a silyl group (a silyl group having preferably 3 to 38 carbon atoms and more preferably 3 to 18 carbon atoms, such as a trimethylsilyl group, a triethylsilyl group, a tributylsilyl group, a t-butyldimethylsilyl group, and a t-hexyldimethylsilyl group);
a hydroxy group; a cyano group; a nitro group; a morpholino group;
an alkoxy group (an alkoxy group having preferably 1 to 48 carbon atoms and more preferably 1 to 24 carbon atoms, such as a methoxy group, an ethoxy group, a 1-butoxy group, a 2-butoxy group, an isopropoxy group, a t-butoxy group, a dodecyloxy group, and a cycloalkyloxy group (for example, a cyclopentyloxy group or a cyclohexyloxy group));
an aryloxy group (an aryloxy group having preferably 6 to 48 carbon atoms and more preferably 6 to 24 carbon atoms, such as a phenoxy group and a 1-naphthoxy group);
an alkenyloxy group (an alkenyloxy group having preferably 2 to 6 carbon atoms, such as a vinyloxy group, a 1-propenyloxy group, a 2-n-propenyloxy group (an allyloxy group), a 1-n-butenyloxy group, and a prenyloxy group);
a heterocyclic oxy group (a heterocyclic oxy group having preferably 1 to 32 carbon atoms and more preferably 1 to 18 carbon atoms, such as a 1-phenyltetrazol-5-yloxy group and a 2-tetrahydropyranyloxy group);
a silyloxy group (a silyloxy group having preferably 1 to 32 carbon atoms and more preferably 1 to 18 carbon atoms, such as a trimethylsilyloxy group, a t-butyldimethylsilyloxy group, and a diphenylmethylsilyloxy group);
an acyloxy group (an acyloxy group having preferably 2 to 48 carbon atoms and more preferably 2 to 24 carbon atoms, such as an acetoxy group, a pivaloyloxy group, a benzoyloxy group, a dodecanoyloxy group, an acryloyloxy group, and a methacryloyloxy group);
a hydroxyalkyleneoxy group (a hydroxyalkyleneoxy group having preferably 2 to 10 carbon atoms, such as a hydroxyethyleneoxy group);
an alkoxycarbonyloxy group (an alkoxycarbonyloxy group having preferably 2 to 48 carbon atoms and more preferably 2 to 24 carbon atoms, such as an ethoxycarbonyloxy group, a t-butoxycarbonyloxy group, and a cycloalkyloxycarbonyloxy group (for example, a cyclohexyloxycarbonyloxy group));
an aryloxycarbonyloxy group (an aryloxycarbonyloxy group having preferably 7 to 32 carbon atoms and more preferably 7 to 24 carbon atoms, such as a phenoxycarbonyloxy group);
a carbamoyloxy group (a carbamoyloxy group having preferably 1 to 48 carbon atoms and more preferably 1 to 24 carbon atoms, such as an N,N-dimethylcarbamoyloxy group, an N-butylcarbamoyloxy group, an N-phenylcarbamoyloxy group, and an N-ethyl-N-phenylcarbamoyloxy group);
a sulfamoyloxy group (a sulfamoyloxy group having preferably 1 to 32 carbon atoms and more preferably 1 to 24 carbon atoms, such as an N,N-diethylsulfamoyloxy group and an N-propylsulfamoyloxy group);
an alkylsulfonyloxy group (an alkylsulfonyloxy group having preferably 1 to 38 carbon atoms and more preferably 1 to 24 carbon atoms, such as a methylsulfonyloxy group, a hexadecylsulfonyloxy group, and a cyclohexylsulfonyloxy group);
an arylsulfonyloxy group (an arylsulfonyloxy group having preferably 6 to 32 carbon atoms and more preferably 6 to 24 carbon atoms, such as a phenylsulfonyloxy group);
an acyl group (an acyl group having preferably 1 to 48 carbon atoms and more preferably 1 to 24 carbon atoms, such as a formyl group, an acetyl group, an acryloyl group, a methacryloyl group, a pivaloyl group, a benzoyl group, a tetradecanoyl group, and a cyclohexanoyl group);
an alkoxycarbonyl group (an alkoxycarbonyl group having preferably 2 to 48 carbon atoms and more preferably 2 to 24 carbon atoms, such as a methoxycarbonyl group, an ethoxycarbonyl group, an octadecyloxycarbonyl group, a cyclohexyloxycarbonyl group, and a 2,6-di-tert-butyl-4-methylcyclohexyloxycarbonyl group);
an aryloxycarbonyl group (an aryloxycarbonyl group having preferably 7 to 32 carbon atoms and more preferably 7 to 24 carbon atoms, such as a phenoxycarbonyl group);
a carbamoyl group (a carbamoyl group having preferably 1 to 48 carbon atoms and more preferably 1 to 24 carbon atoms, such as a carbamoyl group, an N,N-diethylcarbamoyl group, an N-ethyl-N-octylcarbamoyl group, an N,N-dibutylcarbamoyl group, an N-propylcarbamoyl group, an N-phenylcarbamoyl group, an N-methyl-N-phenylcarbamoyl group, and an N,N-dicyclohexylcarbamoyl group);
an amino group (an amino group having preferably 32 or less carbon atoms and more preferably 24 or less carbon atoms, such as an amino group, a methylamino group, an N,N-dimethylamino group, an N,N-dibutylamino group, a tetradecylamino group, a 2-ethylhexylamino group, and a cyclohexylamino group);
an anilino group (an anilino group having preferably 6 to 32 carbon atoms and more preferably 6 to 24 carbon atoms, such as an anilino group and an N-methylanilino group);
a heterocyclic amino group (a heterocyclic amino group having preferably 1 to 32 carbon atoms and more preferably 1 to 18 carbon atoms, such as a 4-pyridylamino group);
a carboxamide group (a carboxamide group having preferably 2 to 48 carbon atoms and more preferably 2 to 24 carbon atoms, such as an acetamide group, a benzamide group, a tetradecaneamide group, a pivaloylamide group, and a cyclohexaneamide group);
a ureido group (a ureido group having preferably 1 to 32 carbon atoms and more preferably 1 to 24 carbon atoms, such as a ureido group, an N,N-dimethylureido group, and an N-phenylureido group);
an imide group (an imide group having preferably 36 or less carbon atoms and more preferably 24 or less carbon atoms, such as an N-succinimide group and an N-phthalimide group);
an alkoxycarbonylamino group (an alkoxycarbonylamino group having preferably 2 to 48 carbon atoms and more preferably 2 to 24 carbon atoms, such as a methoxycarbonylamino group, an ethoxycarbonylamino group, a t-butoxycarbonylamino group, an octadecyloxycarbonylamino group, and a cyclohexyloxycarbonylamino group);
an aryloxycarbonylamino group (an aryloxycarbonylamino group having preferably 7 to 32 carbon atoms and more preferably 7 to 24 carbon atoms, such as a phenoxycarbonylamino group);
a sulfonamide group (a sulfonamide group having preferably 1 to 48 carbon atoms and more preferably 1 to 24 carbon atoms, such as a methanesulfonamide group, a butanesulfonamide group, a benzenesulfonamide group, a hexadecanesulfonamide group, and a cyclohexanesulfonamide group);
a sulfamoylamino group (a sulfamoylamino group having preferably 1 to 48 carbon atoms and more preferably 1 to 24 carbon atoms, such as an N,N-dipropylsulfamoylamino group and an N-ethyl-N-dodecylsulfamoylamino group);
an azo group (an azo group having preferably 1 to 32 carbon atoms and more preferably 1 to 24 carbon atoms, such as a phenylazo group and a 3-pyrazolylazo group);
an alkylthio group (an alkylthio group having preferably 1 to 48 carbon atoms and more preferably 1 to 24 carbon atoms, such as a methylthio group, an ethylthio group, an octylthio group, and a cyclohexylthio group);
an arylthio group (an arylthio group having preferably 6 to 48 carbon atoms and more preferably 6 to 24 carbon atoms, such as a phenylthio group);
a heterocyclic thio group (a heterocyclic thio group having preferably 1 to 32 carbon atoms and more preferably 1 to 18 carbon atoms, such as a 2-benzothiazolylthio group, a 2-pyridylthio group, and a 1-phenyltetrazolylthio group);
an alkylsulfinyl group (an alkylsulfinyl group having preferably 1 to 32 carbon atoms and more preferably 1 to 24 carbon atoms, such as a dodecanesulfinyl group);
an arylsulfinyl group (an arylsulfinyl group having preferably 6 to 32 carbon atoms and more preferably 6 to 24 carbon atoms, such as a phenylsulfinyl group);
an alkylsulfonyl group (an alkylsulfonyl group having preferably 1 to 48 carbon atoms and more preferably 1 to 24 carbon atoms, such as a methylsulfonyl group, an ethylsulfonyl group, a propylsulfonyl group, a butylsulfonyl group, an isopropylsulfonyl group, a 2-ethylhexylsulfonyl group, a hexadecylsulfonyl group, an octylsulfonyl group, and a cyclohexylsulfonyl group);
an arylsulfonyl group (an arylsulfonyl group having preferably 6 to 48 carbon atoms and more preferably 6 to 24 carbon atoms, such as a phenylsulfonyl group and a 1-naphthylsulfonyl group);
a sulfamoyl group (a sulfamoyl group having preferably 32 or less carbon atoms and more preferably 24 or less carbon atoms, such as a sulfamoyl group, an N,N-dipropylsulfamoyl group, an N-ethyl-N-dodecylsulfamoyl group, an N-ethyl-N-phenylsulfamoyl group, an N-cyclohexylsulfamoyl group, and an N-(2-ethylhexyl)sulfamoyl group);
a phosphonyl group (a phosphonyl group having preferably 1 to 32 carbon atoms and more preferably 1 to 24 carbon atoms, such as a phenoxyphosphonyl group, an octyloxyphosphonyl group, and a phenylphosphonyl group);
a phosphinoylamino group (a phosphinoylamino group having preferably 1 to 32 carbon atoms and more preferably 1 to 24 carbon atoms, such as a diethoxyphosphinoylamino group and a dioctyloxyphosphinoylamino group);
epoxy groups; —NHCOCH₃; —SO₂NHC₂H₄OCH₃; —NHSO₂CH₃; and
two or more of these may be combined.

These substituents may be further substituted with these substituents. In addition, in a case of having two or more of the substituents, the substituents may be the same or different from each other. Furthermore, if possible, these substituents may be bonded to each other to form a ring.

### [Retardation Film]

The retardation film according to the embodiment of the present invention is a retardation film including a support in which an in-plane retardation exhibits reverse wavelength dispersibility, and a liquid crystal layer directly laminated on the support.

In addition, the support included in the retardation film according to the embodiment of the present invention is a polymer film which has been subjected to a stretching treatment in at least one in-plane direction.

In addition, the liquid crystal layer included in the retardation film according to the embodiment of the present invention is a positive C-plate obtained by immobilizing an alignment state of a liquid crystal composition containing a liquid crystal compound.

In addition, in the retardation film according to the embodiment of the present invention, a photoelastic constant of the support is 30×10⁻¹² Pa or less, or a product of the photoelastic constant (unit: Pa) of the support and a thickness (unit: μm) of the support is 2000×10⁻¹² Pa·μm or less.

In the present invention, as described above, by using a retardation film including a support consisting of a polymer film in which an in-plane retardation exhibits reverse wavelength dispersibility and a photoelastic constant is 30×10⁻¹² Pa or less or a product of the photoelastic constant and a thickness is 2000×10⁻¹² Pa·μm or less, and a liquid crystal layer (positive C-plate) directly laminated on the support, it is possible to produce an image display device in which the occurrence of mounting unevenness is suppressed.

The mechanism is not clear in detail, but is presumed to be as follows.

First, the retardation film needs to be bonded to a display element in a case of being incorporated into an image display device, but the present inventors presume that the cause of the occurrence of mounting unevenness is generated in a case of bonding the retardation film to the display element.

In addition, the present inventors presume that the cause of the occurrence of mounting unevenness is that a region where a retardation is unintentionally changed in the plane of the support is generated due to unevenness of stress inevitably generated in the plane of the support in a case of bonding the retardation film to the display element, from the results of Comparative Example 4 of the present specification, that is, an example corresponding to Example 1 of the above-described Patent Document 1.

Therefore, in the present invention, it is considered that, by using a support in which a photoelastic constant is 30×10⁻¹² Pa or less or a product of the photoelastic constant and a thickness is 2000×10⁻¹² Pa·μm or less, a phase difference is less likely to be generated with respect to stress generated in the plane during bonding, and thus it is possible to produce an image display device in which the occurrence of mounting unevenness is suppressed.

A thickness of the retardation film according to the embodiment of the present invention is preferably 2 to 210 μm, more preferably 3 to 110 μm, and still more preferably 5 to 80 μm. In a case where the retardation film has a plurality of layers, the thickness of the retardation film refers to the total film thickness including the layers.

### [Support]

The support included in the retardation film according to the embodiment of the present invention is a support in which an in-plane retardation exhibits reverse wavelength dispersibility.

Here, the expression “the in-plane retardation exhibits reverse wavelength dispersibility” means that, in a case where an in-plane retardation (Re) value of a layer (film) at a specific wavelength (visible light range) is measured, the Re value increases as a measurement wavelength increases, and in the present invention, the expression means that a relationship of Re(450)/Re(550)<1.00 is satisfied.

In addition, in the support, Re(450)/Re(550) is preferably 0.60 or more and 1.00 or less, more preferably 0.70 or more and 1.00 or less, and still more preferably 0.75 or more and 0.95 or less.

Furthermore, the in-plane retardation of the support preferably satisfies a relationship of Re(650)/Re(550)>1.00. Re(650)/Re(550) is preferably 1.00 or more and 1.30 or less, more preferably 1.00 or more and 1.25 or less, and still more preferably 1.00 or more and 1.20 or less.

In addition, the support included in the retardation film according to the embodiment of the present invention is a polymer film that has been subjected to a stretching treatment in at least one in-plane direction, and is preferably a polymer film that has been subjected to a monoaxial stretching treatment or a biaxial stretching treatment.

Examples of the polymer contained in such a polymer film include polycarbonate; polyolefins such as polyethylene and polypropylene; polyesters such as polyethylene terephthalate and polybutylene terephthalate; polyarylene sulfides such as polyphenylene sulfide; polyvinyl alcohol; polyarylate; cellulose ester polymers such as cellulose acylate; polyethersulfone; polysulfone; polyallylsulfone; polyvinyl chloride; and cyclic olefin polymers such as a norbornene polymer.

Among these, from the reason that the aligning properties of the retardation film are improved and the adhesiveness between the support and the liquid crystal layer is improved, polycarbonate or polyester is preferable.

In addition, the support included in the retardation film according to the embodiment of the present invention is also preferably a resin including a resin exhibiting positive birefringence and a resin exhibiting negative birefringence. Examples of these resins include the resins described in JP2023-180135A and JP2023-180201A.

In addition, specific examples of the resin exhibiting positive birefringence include a cellulose-based resin, and examples thereof include cellulose-based resins described in paragraphs 0023 to 0029 of JP2023-180135A or paragraphs 0032 to 0037 of JP2023-180201A.

In addition, specific examples of the resin exhibiting negative birefringence include an ester-based resin, and examples thereof include ester resins described in paragraphs 0030 to 0043 of JP2023-180135A or paragraphs 0038 to 0051 of JP2023-180201A.

In addition, the support included in the retardation film according to the embodiment of the present invention has a photoelastic constant of 30×10⁻¹² Pa or less, or a product of the photoelastic constant and the thickness is 2,000×10⁻¹² Pa·μm or less.

Here, the photoelastic constant refers to a rate of change of the phase difference with respect to the stress, and the photoelastic constant of the support can be measured by cutting out a test piece having a length of 50 mm and a width of 10 mm from the support and using a spectroscopic ellipsometer (for example, Spectroellipsometer M-220 manufactured by JASCO Corporation). The photoelastic constant is measured in an environment of a temperature of 25 °C and a humidity of 60%, and in a case where the photoelastic constant depends on the measurement orientation (slow axis/fast axis) of the film, an average value thereof is adopted.

In addition, the thickness of the support is calculated as an average value of any five points measured by cross-sectional observation with an optical microscope.

In the present invention, from the reason that an image display device in which the occurrence of mounting unevenness is further suppressed can be produced, the photoelastic constant of the support is preferably 25×10⁻¹² Pa or less, more preferably in a range of 1×10⁻¹² Pa or more and 25×10⁻¹² Pa or less, still more preferably in a range of 1×10⁻¹² Pa or more and 22×10⁻¹² Pa or less, and particularly preferably in a range of 1×10⁻¹² Pa or more and 20×10⁻¹² Pa or less.

In the present invention, from the reason that an image display device in which the occurrence of mounting unevenness is further suppressed can be produced, the product of the photoelastic constant (unit: Pa) and the thickness (unit: μm) of the support is preferably less than 1,800×10⁻¹² Pa·μm, and more preferably 1,500×10⁻¹² Pa·μm or less. The lower limit value of the boiling point of the solvent is not particularly limited, but is preferably 10×10⁻¹² Pa·μm or higher, more preferably 20×10⁻¹² Pa·μm or higher, and still more preferably 30×10⁻¹² Pa·μm or higher.

In the present invention, from the reason that oblique light leakage is suppressed in a case of being used in an image display device, the support is preferably a positive A plate.

Here, in the present specification, the positive A-plate is defined as follows.

That is, the positive A-plate satisfies a relationship of an expression (A1) in a case where a refractive index in the slow axis direction in a film plane (in a direction such that the in-plane refractive index is maximum) is defined as nx, a refractive index in the in-plane direction orthogonal to the in-plane slow axis is defined as ny, and a thickness-direction refractive index is defined as nz. In the positive A-plate, Rth indicates a positive value.

nx>ny≈nz Expression (A1)

The symbol “≈” encompasses not only a case where both sides are completely the same as each other but also a case where both sides are substantially the same as each other. As the expression “substantially the same”, for example, “ny~nz” includes a case where (ny−nz)×d (here, d is a thickness of the film) is −10 to 10 nm, preferably −5 to 5 nm.

Re(550) of the support is preferably 10 nm or more and 300 nm or less, more preferably 50 nm or more and 200 nm or less, and still more preferably 100 nm or more and 160 nm or less.

In addition, Rth(550) of the support is preferably 10 nm or more and 200 nm or less, more preferably 50 nm or more and 150 nm or less, and still more preferably 60 nm or more and 130 nm or less.

In the present invention, the support is preferably transparent. The term “transparent” in the present invention indicates that the transmittance of visible light is 60% or more, preferably 80% or more and more preferably 90% or more.

The thickness of the support is not particularly limited, but is preferably 1 to 200 μm and more preferably 2 to 100 μm.

### [Liquid Crystal Layer]

The liquid crystal layer included in the retardation film according to the embodiment of the present invention is a liquid crystal layer directly laminated on the above-described support. That is, there is no other member (for example, a so-called alignment film) between the support and the liquid crystal layer.

In addition, the liquid crystal layer included in the retardation film according to the embodiment of the present invention is a positive C-plate obtained by immobilizing an alignment state of a liquid crystal composition containing a liquid crystal compound.

Here, since the liquid crystal layer immobilizes the alignment state of the liquid crystal composition as described above, the liquid crystal compound contained in the liquid crystal layer does not need to exhibit liquid crystallinity.

In addition, in the present specification, the positive C-plate is defined as follows.

The positive C-plate satisfies a relationship of Expression (C1) in a case where a refractive index in the slow axis direction in the liquid crystal layer (in a direction such that the in-plane refractive index is maximum) is defined as nx, a refractive index in the in-plane direction orthogonal to the in-plane slow axis is defined as ny, and a thickness-direction refractive index is defined as nz. In the positive C-plate, Rth exhibits a negative value.

nx≈ny<nz Expression (C1)

The symbol “≈” encompasses not only a case where both sides are completely the same as each other but also a case where both sides are substantially the same as each other. The expression “substantially the same” means that, for example, a case where (nx−ny)×d (in which d is a thickness of a film) is 0 to 10 nm and preferably 0 to 5 nm is also included in “nx≈ny”.

Re(550) of the liquid crystal layer is preferably 0 nm or more and 10 nm or less, more preferably 0 nm or more and 5 nm or less, and still more preferably 0 nm or more and 2 nm or less.

Rth(550) of the liquid crystal layer is preferably −200 nm or more and −10 nm or less, more preferably −180 nm or more and −50 nm or less, and still more preferably −150 nm or more and −80 nm or less.

In the present invention, it is preferable that the liquid crystal layer exhibits reverse wavelength dispersibility for a reason that oblique light leakage is suppressed in a case of being used in the image display device. More specifically, it is preferable that a retardation in the thickness direction exhibits reverse wavelength dispersibility.

Here, the “retardation in the thickness direction exhibits reverse wavelength dispersibility” means that, in a case where a retardation (Rth) value in the thickness direction at a specific wavelength (visible light range) of the liquid crystal layer alone is measured, an absolute value of the Rth value increases as a measurement wavelength increases, and in the present invention, it refers to a case where a relationship of Rth(450)/Rth(550)<1.00 is satisfied.

In addition, in the liquid crystal layer, Rth(450)/Rth(550) is preferably 0.60 or more and 1.10 or less, more preferably 0.70 or more and 1.00 or less, and still more preferably 0.75 or more and 0.95 or less.

Furthermore, it is preferable that the retardation in the thickness direction of the liquid crystal layer satisfies a relationship of Rth(650)/Rth(550)>1.00. Rth(650)/Rth(550) is preferably 1.00 or more and 1.30 or less, more preferably 1.00 or more and 1.25 or less, and still more preferably 1.00 or more and 1.20 or less.

In the present invention, the thickness of the liquid crystal layer is not particularly limited, but is preferably 0.5 to 5 μm, more preferably 0.5 to 4 μm, and still more preferably 0.5 to 3 μm.

### <Liquid Crystal Composition>

As described above, the liquid crystal layer included in the retardation film according to the embodiment of the present invention is a positive C-plate obtained by immobilizing an alignment state of a liquid crystal composition containing a liquid crystal compound.

### (Liquid Crystal Compound)

The liquid crystal compound contained in the liquid crystal composition is not particularly limited, and a known liquid crystal compound in the related art can be used.

In general, the liquid crystal compound can be classified into a rod-like type and a disk-like type according to the shape thereof. Each of the types can further be classified into a low-molecular-weight type and a high-molecular-weight type. The “high-molecular-weight” generally refers to a compound having a degree of polymerization of 100 or more (Polymer Physics-Phase Transition Dynamics, written by Masao Doi, p. 2, published by Iwanami Shoten, 1992).

In the present invention, it is preferable to use a rod-like liquid crystal compound. A mixture of two or more kinds of rod-like liquid crystal compounds may be used.

As the rod-like liquid crystal compound, for example, those described in claim 1 of JP1999-513019A (JP-H11-513019A) or paragraphs 0026 to 0098 of JP2005-289980A can be preferably used, but the rod-like liquid crystal compound is not limited thereto.

In the present invention, from the viewpoint of improving the durability of the liquid crystal layer, the above-described liquid crystal compound preferably has a polymerizable group and more preferably has two or more polymerizable groups.

Here, the polymerizable group is not particularly limited, but is preferably a radically polymerizable group or a cationically polymerizable group.

A known radically polymerizable group can be used as the radically polymerizable group, and suitable examples thereof include an acryloyloxy group or a methacryloyloxy group.

In this case, it is known that the acryloyloxy group generally has a high polymerization rate, and from the viewpoint of improving productivity, the acryloyloxy group is preferable. However, the methacryloyloxy group can also be used as the polymerizable group.

A known cationically polymerizable group can be used as the cationically polymerizable group, and specific examples thereof include an alicyclic ether group, a cyclic acetal group, a cyclic lactone group, a cyclic thioether group, a spiro orthoester group, and a vinyloxy group. Among these, an alicyclic ether group or a vinyloxy group is suitable, and an epoxy group, an oxetanyl group, or a vinyloxy group is particularly preferable.

Examples of a particularly preferred polymerizable group include a polymerizable group represented by any one of Formulae (P-1) to (P-20).

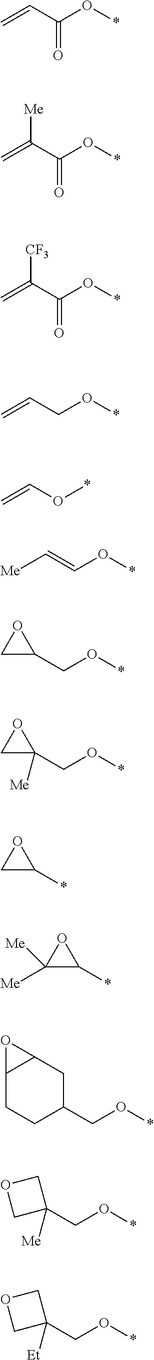

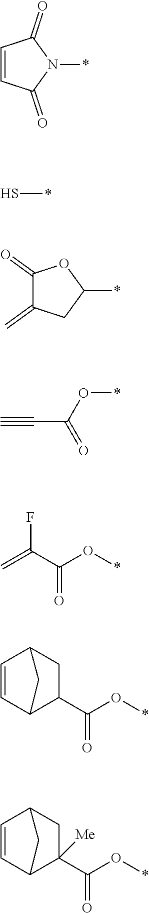

In the present invention, from the viewpoint of improving the aligning properties of the retardation film, the above-described liquid crystal compound is preferably a liquid crystal compound having reverse wavelength dispersibility, and more preferably a compound represented by Formula (A).

L¹-SP¹-D⁵-(A¹)ₐ₁-D³-(G¹)_{g1}-D¹-Ar-D²-(G²)_{g2}-D⁴-(A²)ₐ₂-D⁶-SP²-L² (A)

In Formula (A), a1, a2, g1, and g2 each independently represent 0 or 1. However, at least one of a1 or g1 represents 1 and at least one of a2 or g2 represents 1.

In addition, D¹, D², D³, D⁴, D⁵, and D⁶ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms.

In addition, G¹ and G² each independently represent an aromatic ring having 6 to 20 carbon atoms, which may have a substituent, or a divalent alicyclic hydrocarbon group having 5 to 20 carbon atoms, which may have a substituent, where one or more of —CH₂—'s constituting the alicyclic hydrocarbon group may be substituted with —O—, —S—, or —NH—.

In addition, A¹ and A² each independently represent an aromatic ring having 6 to 20 carbon atoms, which may have a substituent, or a divalent alicyclic hydrocarbon group having 5 to 20 carbon atoms, which may have a substituent, where one or more of —CH₂—'s constituting the alicyclic hydrocarbon group may be replaced with —O—, —S—, or —NH—.

In addition, SP¹ and SP² each independently represent a single bond or a divalent aliphatic hydrocarbon group having 1 to 20 carbon atoms. Here, one or more of —CH₂—'s constituting the aliphatic hydrocarbon group may be replaced with —O—, —S—, —NH—, —N(Q)-, or —CO—. Q represents a substituent.

In addition, L¹ and L² each independently represent a monovalent organic group, where at least one of L¹ or L² represents a polymerizable group. Here, in a case where Ar is an aromatic ring represented by Formula (Ar-3), at least one of L¹, L², or L³ or L⁴ in Formula (Ar-3) represents a polymerizable group.

In addition, Ar represents any aromatic ring selected from the group consisting of groups represented by Formulae (Ar-1) to (Ar-7) described later.

In Formula (A), it is preferable that all of a1, a2, g1, and g2 are 1 for the reason that the liquid crystal composition easily exhibits a liquid crystalline state of a smectic phase.

In addition, from the reason that the durability of the liquid crystal layer to be produced is improved, it is preferable that both a1 and a2 are 0 and both g1 and g2 are 1.

In Formula (A), examples of the divalent linking group represented by one aspect of D¹, D², D³, D⁴, D⁵, and D⁶ include —CO—, —O—, —S—, —C(═S)—, —CCR¹R²—, —CR³═CR⁴—, —NR⁵—, or a divalent linking group consisting of a combination of two or more of these groups. R1 to R5 each independently represent a hydrogen atom, a fluorine atom, or an alkyl group having 1 to 12 carbon atoms.

Specific examples of the divalent linking group include —CO—, —O—, —CO—O—, —C(═S)O—, —CR¹R²—, —CR¹R²—CR¹R²—, —O—CR¹R²—, —CR¹R²—O—CR¹R²—, —CO—O—CR¹R²—, —O—CO—CR¹R²—, —CR¹R²—O—CO—CR¹R²—, —CR¹R²—CO—O—CR¹R²—, —NR⁵—CR¹R²—, and —CO—NR⁵—. R¹, R² and R⁵ each independently represent a hydrogen atom, a fluorine atom, or an alkyl group having 1 to 12 carbon atoms.

Among these, any of —CO—, —O—, or —CO—O— is preferable.

In Formula (A), examples of the aromatic ring having 6 to 20 carbon atoms, represented by one aspect of G¹ and G², include aromatic hydrocarbon rings such as a benzene ring, a naphthalene ring, an anthracene ring, and a phenanthroline ring; and aromatic heterocyclic rings such as a furan ring, a pyrrole ring, a thiophene ring, a pyridine ring, a thiazole ring, and a benzothiazole ring. Among these, a benzene ring (for example, a 1,4-phenyl group) is preferable.

In Formula (A), the divalent alicyclic hydrocarbon group having 5 to 20 carbon atoms, represented by one aspect of G¹ and G², is preferably a 5-membered ring or a 6-membered ring. In addition, the alicyclic hydrocarbon group may be saturated or unsaturated, but a saturated alicyclic hydrocarbon group is preferable. As the divalent alicyclic hydrocarbon group represented by G¹ and G², for example, the description of paragraph [0078] of JP2012-21068A can be referred to, the contents of which are incorporated herein by reference.

In the present invention, G¹ and G² in Formula (A) are each preferably a cycloalkane ring for the reason that durability of the liquid crystal layer is improved.

Specific examples of the cycloalkane ring include a cyclohexane ring, a cycloheptane ring, a cyclooctane ring, a cyclododecane ring, and a cyclodocosane ring.

Among these, a cyclohexane ring is preferable, a 1,4-cyclohexylene group is more preferable, and a trans-1,4-cyclohexylene group is still more preferable.

In addition, with regard to G¹ and G² in Formula (A), examples of the substituent which may be included in the aromatic ring having 6 to 20 carbon atoms and the divalent alicyclic hydrocarbon group having 5 to 20 carbon atoms include the substituents described in the above substituent group A; and among these, an alkyl group, an alkoxy group, an alkoxycarbonyl group, an alkylcarbonyloxy group, or a halogen atom is preferable.

In Formula (A), examples of the aromatic ring having 6 to 20 or more carbon atoms, represented by one aspect of A¹ and A², include the same aromatic rings as those described for G¹ and G² in Formula (A).

In addition, in Formula (A), examples of the divalent alicyclic hydrocarbon group having 5 to 20 carbon atoms, represented by one aspect of A¹ and A², include the same groups as those described for G¹ and G² in Formula (A).

In A¹ and A², examples of the substituent which may be included in the aromatic ring having 6 to 20 carbon atoms or the divalent alicyclic hydrocarbon group having 5 to 20 carbon atoms include the same as those described for the substituent which may be included in each of G¹ and G² in Formula (A).

Examples of the divalent aliphatic hydrocarbon group having 1 to 20 carbon atoms, represented by one aspect of SP¹ and SP² in Formula (A), include a linear or branched alkylene group having 1 to 20 carbon atoms, a linear or branched alkenylene group having 1 to 20 carbon atoms, and a linear or branched alkynylene group having 1 to 20 carbon atoms.

As the linear or branched alkylene group having 1 to 20 carbon atoms, an alkylene group having 1 to 12 carbon atoms is preferable and an alkylene group having 1 to 10 carbon atoms is more preferable; and suitable examples thereof include a methylene group, an ethylene group, a propylene group, a butylene group, a pentylene group, and a hexylene group.

As the linear or branched alkenylene group having 1 to 20 carbon atoms, an alkenylene group having 2 to 10 carbon atoms is preferable and an alkenylene group having 2 to 4 carbon atoms is more preferable; and suitable examples thereof include an ethenylene group.

As the linear or branched alkynylene group having 1 to 20 carbon atoms, an alkynylene group having 2 to 10 carbon atoms is preferable and an alkynylene group having 2 to 4 carbon atoms is more preferable; and suitable examples thereof include an ethynylene group.

As described above, one or more of —CH₂—'s constituting the aliphatic hydrocarbon group may be substituted with —O—, —S—, —NH—, —N(Q)-, or —CO—; and examples of the substituent represented by Q include the substituents described in the above substituent group A. Among these, an alkyl group, an alkoxy group, an alkoxycarbonyl group, an alkylcarbonyloxy group, or a halogen atom is preferable.

In Formula (A), examples of the monovalent organic group represented by L¹ and L² include the substituents described in the above substituent group A; and among these, suitable examples thereof include an alkyl group, an aryl group, a heteroaryl group, an alkoxy group, a cyano group, and a carboxy group.

The alkyl group may be linear, branched, or cyclic, but is preferably linear. The number of carbon atoms in the alkyl group is preferably 1 to 30, more preferably 1 to 20, and still more preferably 1 to 10.

In addition, the aryl group may be monocyclic or polycyclic, but is preferably monocyclic. The number of carbon atoms in the aryl group is preferably 6 to 25 and more preferably 6 to 10.

In addition, the heteroaryl group may be monocyclic or polycyclic. The number of heteroatoms constituting the heteroaryl group is preferably 1 to 3. The heteroatom constituting the heteroaryl group is preferably a nitrogen atom, a sulfur atom, or an oxygen atom. The number of carbon atoms in the heteroaryl group is preferably 6 to 18 and more preferably 6 to 12.

In addition, the alkyl group, the aryl group, and the heteroaryl group may be unsubstituted or may have a substituent. Examples of the substituent include the substituents described in the above substituent group A; and among these, an alkyl group, an alkoxy group, an alkoxycarbonyl group, an alkylcarbonyloxy group, or a halogen atom is preferable.

In addition, suitable examples of the polymerizable group represented by at least one of L¹ or L² include the polymerizable group represented by any of Formulae (P-1) to (P-20) described above.

In Formula (A), as described above, Ar represents any aromatic ring selected from the group consisting of groups represented by Formulae (Ar-1) to (Ar-7). In Formulae (Ar-1) to (Ar-7), * represents a bonding position to D¹ or D² in Formula (A).

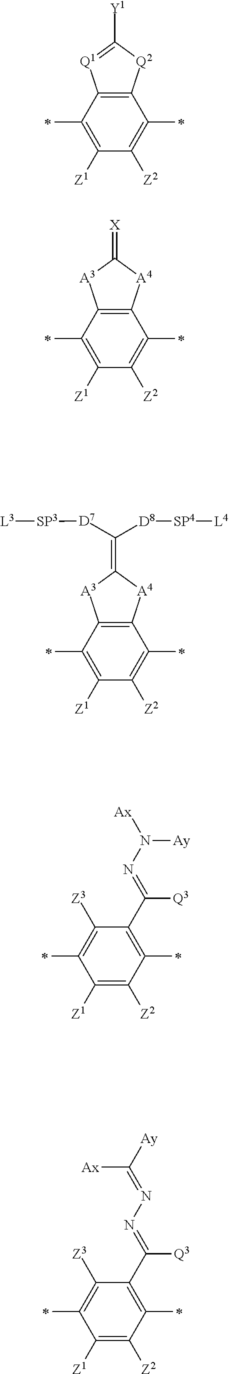

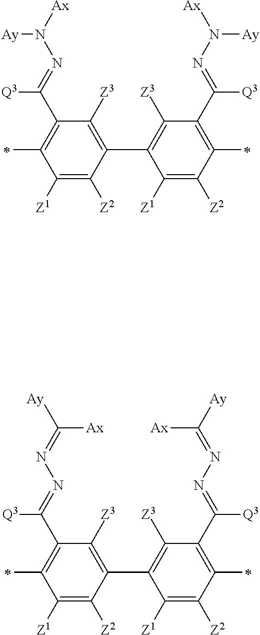

In Formula (Ar-1), Q¹ represents N or CH, Q² represents —S—, —O—, or —N(R⁶)—, where R⁶ represents a hydrogen atom or an alkyl group having 1 to 6 carbon atoms, Y¹ represents an aromatic hydrocarbon group having 6 to 12 carbon atoms, which may have a substituent, an aromatic heterocyclic group having 3 to 12 carbon atoms, which may have a substituent, or an alicyclic hydrocarbon group having 6 to 20 carbon atoms, which may have a substituent, and one or more of —CH₂—'s constituting the alicyclic hydrocarbon group may be replaced with —O—, —S—, or —NH—.

Here, specific examples of the alkyl group having 1 to 6 carbon atoms, represented by one aspect of R⁶, include a methyl group, an ethyl group, a propyl group, an isopropyl group, a n-butyl group, an isobutyl group, a sec-butyl group, a tert-butyl group, a n-pentyl group, and a n-hexyl group.

Examples of the aromatic hydrocarbon group having 6 to 12 carbon atoms, represented by one aspect of Y¹, include aryl groups such as a phenyl group, a 2,6-diethylphenyl group, and a naphthyl group.

Examples of the aromatic heterocyclic group having 3 to 12 carbon atoms, represented by one aspect of Y¹, include a heteroaryl group such as a thienyl group, a thiazolyl group, a furyl group, a pyridyl group, a benzofuryl group, and a benzothiazolyl group; and a group obtained by removing one hydrogen atom from any of an indole ring, a benzofuran ring, a benzothiophene ring, a benzimidazole ring, a benzothiazole ring, or a benzoxazole ring. Among these, as the aromatic heterocyclic group having 3 to 12 carbon atoms, represented by Y¹, a group obtained by removing one hydrogen atom from a benzofuran ring or a benzothiazole ring is preferable.

Examples of the alicyclic hydrocarbon group having 6 to 20 carbon atoms, represented by one aspect of Y¹, include a cyclohexylene group, a cyclopentylene group, a norbornylene group, and an adamantylene group.

In addition, examples of the substituent which may be included in Y¹ include the substituents described in the above substituent group A; and among these, an alkyl group, an alkoxy group, an alkoxycarbonyl group, an alkylcarbonyloxy group, a nitro group, a cyano group, or a halogen atom is preferable.

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a monovalent aromatic heterocyclic group having 6 to 20 carbon atoms, a halogen atom, a cyano group, a nitro group, —OR⁷, —NR⁸R⁹, —SR¹⁰, —COOR¹¹, or —COR¹², where R⁷ to R¹² each independently represent a hydrogen atom or an alkyl group having 1 to 6 carbon atoms and Z¹ and Z² may be bonded to each other to form an aromatic ring.

As the monovalent aliphatic hydrocarbon group having 1 to 20 carbon atoms, an alkyl group having 1 to 15 carbon atoms is preferable, an alkyl group having 1 to 8 carbon atoms is more preferable; and specifically, a methyl group, an ethyl group, an isopropyl group, a tert-pentyl group (1,1-dimethylpropyl group), a tert-butyl group, or 1,1-dimethyl-3,3-dimethyl-butyl group is still more preferable, and a methyl group, an ethyl group, or a tert-butyl group is particularly preferable.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and a cyclodecadiene group; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Specific examples of the monovalent aromatic hydrocarbon group having 6 to 20 carbon atoms include a phenyl group, a 2,6-diethylphenyl group, a naphthyl group, and a biphenyl group, and an aryl group having 6 to 12 carbon atoms (particularly, a phenyl group) is preferable.

Specific examples of the monovalent aromatic heterocyclic group having 6 to 20 carbon atoms include a 4-pyridyl group, a 2-furyl group, a 2-thienyl group, a 2-pyrimidinyl group, and a 2-benzothiazolyl group.

Examples of the halogen atom include a fluorine atom, a chlorine atom, a bromine atom, and an iodine atom, and among these, a fluorine atom, a chlorine atom, or a bromine atom is preferable.

On the other hand, specific examples of the alkyl group having 1 to 6 carbon atoms represented by one aspect of R⁷ to R¹⁰ include a methyl group, an ethyl group, a propyl group, an isopropyl group, a n-butyl group, an isobutyl group, a sec-butyl group, a tert-butyl group, a n-pentyl group, and a n-hexyl group.

As described above, Z¹ and Z² may be bonded to each other to form an aromatic ring, and examples of a structure in a case where Z¹ and Z² in Formula (Ar-1) are bonded to each other to form an aromatic ring include a group represented by Formula (Ar-1a). In Formula (Ar-1a), * represents a bonding position to D¹ or D² in Formula (A) described above.

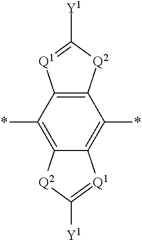

Here, in Formula (Ar-1a), examples of Q¹, Q², and Y¹ include the same as those described in Formula (Ar-1) above.

In addition, in Formulae (Ar-2) and (Ar-3), A³ and A⁴ each independently represent a group selected from the group consisting of —O—, —N(R¹³)—, —S—, and —CO—, and R¹³ represents a hydrogen atom or a substituent.

Examples of the substituent represented by one aspect of R¹³ include the substituents described in the above substituent group A; and among these, an alkyl group, an alkoxy group, an alkoxycarbonyl group, an alkylcarbonyloxy group, or a halogen atom is preferable.

In addition, in Formula (Ar-2), X represents a non-metal atom of Group 14 to Group 16. Here, a hydrogen atom or a substituent may be bonded to the non-metal atom.

In addition, examples of the non-metal atom of Groups 14 to 16, represented by X, include an oxygen atom, a sulfur atom, a nitrogen atom to which a hydrogen atom or a substituent is bonded [═N—R^{N1}, R^{N1} represents a hydrogen atom or a substituent], and a carbon atom to which a hydrogen atom or a substituent is bonded [═C—(R^{C1})₂, R^{C1} represents a hydrogen atom or a substituent].

Suitable examples of the substituent include the substituents described in the above substituent group A; and among these, examples thereof include an alkyl group, an alkoxy group, an alkyl-substituted alkoxy group, a cyclic alkyl group, an aryl group (for example, a phenyl group, a naphthyl group, or the like), a cyano group, an amino group, a nitro group, an alkylcarbonyl group, a sulfo group, and a hydroxyl group.

In addition, in Formula (Ar-3), D⁷ and D⁸ each independently represent a single bond, —CO—, —O—, —S—, —C(═S)—, —CR¹R²—, —CR³═CR⁴—, —NR⁵—, or a divalent linking group consisting of a combination of two or more of these groups, where R¹ to R⁵ each independently represent a hydrogen atom, a fluorine atom, or an alkyl group having 1 to 12 carbon atoms.

Here, specific examples of the divalent linking group include the same groups as those described for D¹, D², D³, D⁴, D⁵, and D⁶ in Formula (A) above.

In addition, in Formula (Ar-3), SP³ and SP⁴ each independently represent a single bond or a divalent aliphatic hydrocarbon group having 1 to 20 carbon atoms. Here, one or more of —CH₂—'s constituting the aliphatic hydrocarbon group may be replaced with —O—, —S—, —NH—, —N(Q)-, or —CO—. Q represents a substituent. Examples of the substituent represented by Q include the substituents described in the above substituent group A; and among these, an alkyl group, an alkoxy group, an alkoxycarbonyl group, an alkylcarbonyloxy group, or a halogen atom is preferable.

Here, examples of the divalent aliphatic hydrocarbon group include the same groups as those described for SP¹ and SP² in Formula (A) above.

In addition, in Formula (Ar-3), L³ and L⁴ each independently represent a monovalent organic group.

Here, examples of the monovalent organic group include the same as those described for L¹ and L² in Formula (A) above.

In addition, in Formulae (Ar-4) to (Ar-7), Ax represents an organic group having 2 to 30 carbon atoms, which has at least one aromatic ring selected from the group consisting of an aromatic hydrocarbon ring and an aromatic heterocyclic ring.

In addition, in Formulae (Ar-4) to (Ar-7), Ay represents a hydrogen atom, an alkyl group having 1 to 12 carbon atoms, which may have a substituent, or an organic group having 2 to 30 carbon atoms which has at least one aromatic ring selected from the group consisting of an aromatic hydrocarbon ring and an aromatic heterocyclic ring.

Here, the aromatic rings in Ax and Ay may have a substituent, and Ax and Ay may be bonded to each other to form a ring.

In addition, Q³ represents a hydrogen atom or an alkyl group having 1 to 6 carbon atoms, which may have a substituent.

Examples of Ax and Ay include those described in paragraphs [0039] to [0095] of WO2014/010325A.

In addition, specific examples of the alkyl group having 1 to 6 carbon atoms, represented by Q³, include a methyl group, an ethyl group, a propyl group, an isopropyl group, a n-butyl group, an isobutyl group, a sec-butyl group, a tert-butyl group, a n-pentyl group, and a n-hexyl group; and examples of the substituent include the substituents described in the above substituent group A. Among these, an alkyl group, an alkoxy group, an alkoxycarbonyl group, an alkylcarbonyloxy group, or a halogen atom is preferable.

Examples of the first liquid crystal compound include a compound represented by General Formula (1) described in JP2010-084032A (particularly, a compound described in paragraphs [0067] to [0073]), a compound represented by General Formula (II) described in JP2016-053709A (particularly, a compound described in paragraphs [0036] to [0043]), a compound represented by General Formula (1) described in JP2016-081035A (particularly, a compound described in paragraphs [0043] to [0055]), and a compound described in paragraphs [0025] to [0056] of WO2021/060427A.

A content of the above-described liquid crystal compound is preferably 50% to 99% by mass and more preferably 60% to 99% by mass with respect to the total solid content of the liquid crystal composition.

The total solid content of the liquid crystal composition means the total mass of components excluding a solvent.

### (Other Polymerizable Compounds)

The liquid crystal composition may contain a polymerizable compound other than the above-described liquid crystal compound. The other polymerizable compounds may or may not have liquid crystallinity. Therefore, among the other polymerizable compounds, the other polymerizable compound having liquid crystal properties can be classified into the above-described liquid crystal compound.

Here, the polymerizable group included in the other polymerizable compounds is not particularly limited; and suitable examples thereof include the polymerizable groups represented by any of Formulae (P-1) to (P-20) described above.

As the other polymerizable compounds, from the reason that the durability of the liquid crystal layer to be formed is more improved, other polymerizable compounds having two to four polymerizable groups are preferable, and other polymerizable compounds having two polymerizable groups are more preferable.

Specific examples of the other polymerizable compounds include compounds represented by Formulae (M1), (M2), and (M3) described in paragraphs “0030” to “0033” of JP2014-077068A, which have liquid crystallinity, and more specifically, specific examples described in paragraphs “0046” to “0055” of the same publication.

In addition, examples of a compound having no liquid crystallinity include polyfunctional acrylates such as polyethylene glycol diacrylate.

A content of the other polymerizable compounds is preferably 0 to 80 parts by mass and more preferably 0 to 70 parts by mass with respect to 100 parts by mass of the above-described liquid crystal compound.

The other polymerizable compounds may be used alone or in combination of two or more thereof.

### (Boronic Acid Monomer)

From the viewpoint of improving the adhesiveness between the support and the liquid crystal layer, the liquid crystal composition preferably contains a boronic acid monomer having a polymerizable group and a boronic acid group represented by Formula (B).

Here, the polymerizable group included in the boronic acid monomer is not particularly limited; and suitable examples thereof include the polymerizable groups represented by any of Formulae (P-1) to (P-20) described above.

The number of boronic acid groups represented by Formula (B), included in the boronic acid monomer, is not particularly limited, and may be one or a plurality (two or more).

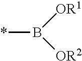

In Formula (B), * represents a bonding position.

R¹ and R² each independently represent a hydrogen atom, an aliphatic hydrocarbon group which may have a substituent, an aryl group which may have a substituent, or a heterocyclic group which may have a substituent, and R¹ and R² may be linked to each other to form a ring.

Examples of the aliphatic hydrocarbon group represented by one aspect of R¹ and R² include a linear or branched alkyl group having 1 to 20 carbon atoms, which may be substituted or unsubstituted, (for example, a methyl group, an ethyl group, an iso-propyl group, and the like), a substituted or unsubstituted cyclic alkyl group having 3 to 20 carbon atoms (for example, a cyclohexyl group and the like), and an alkenyl group having 2 to 20 carbon atoms (for example, a vinyl group and the like).

Examples of the aryl group represented by one aspect of R¹ and R² include a substituted or unsubstituted phenyl group having 6 to 20 carbon atoms (for example, a phenyl group, a tolyl group, and the like), and a substituted or unsubstituted naphthyl group having 10 to 20 carbon atoms.

Examples of the heterocyclic group represented by one aspect of R¹ and R² include a substituted or unsubstituted 5-membered or 6-membered ring group including at least one heteroatom (for example, a nitrogen atom, an oxygen atom, a sulfur atom, and the like); and examples thereof include a pyridyl group, an imidazolyl group, a furyl group, a piperidyl group, and a morpholino group. R¹ and R² may be linked to each other to form a ring, and for example, isopropyl groups of R¹ and R² may be linked to each other to form a 4,4,5,5-tetramethyl-1,3,2-dioxaborolane ring.

Examples of the substituent which may be included in the aliphatic hydrocarbon group, the aryl group, and the heterocyclic group include the substituents described in the above substituent group A.

In Formula (B), as R¹ and R², a hydrogen atom, a linear or branched alkyl group having 1 to 3 carbon atoms, or an aspect in which R¹ and R² are linked to each other to form a ring is preferable, and a hydrogen atom is more preferable.

A molecular weight of the boronic acid monomer is not particularly limited, but from the viewpoint that compatibility with a polyfunctional monomer is excellent, it is preferably 120 to 1,200 and more preferably 180 to 800.

From the viewpoint that adhesiveness between the polarizer and a resin layer is more excellent, examples of a suitable aspect of the boronic acid monomer include a boronic acid monomer represented by Formula (B-1).

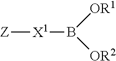

The definitions of R¹ and R² in Formula (B-1) are as described above.

Z represents a polymerizable group. The definition of the polymerizable group is as described above.

X¹ represents a single bond or a divalent linking group. Examples of the divalent linking group include —O—, —CO—, —NH—, —CO—NH—, —COO—, —O—COO—, an alkylene group, an arylene group, a heterocyclic group (heteroaryl group), and a divalent linking group selected from a combination of these groups.

Examples of the combination include an arylene group-COO-arylene group-O-alkylene group- and -arylene group-COO-alkylene group-.

Specific examples of the boronic acid monomer are described below, but the present invention is not limited thereto.

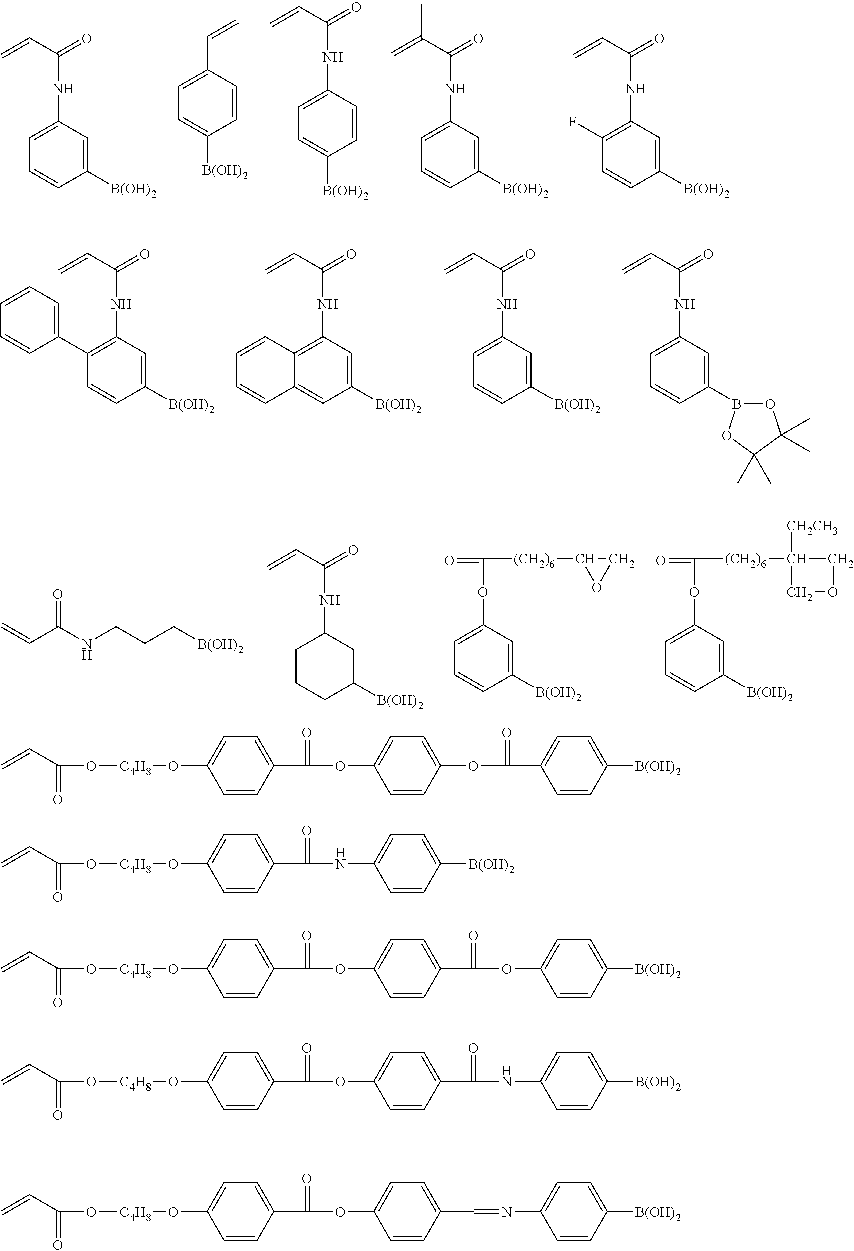

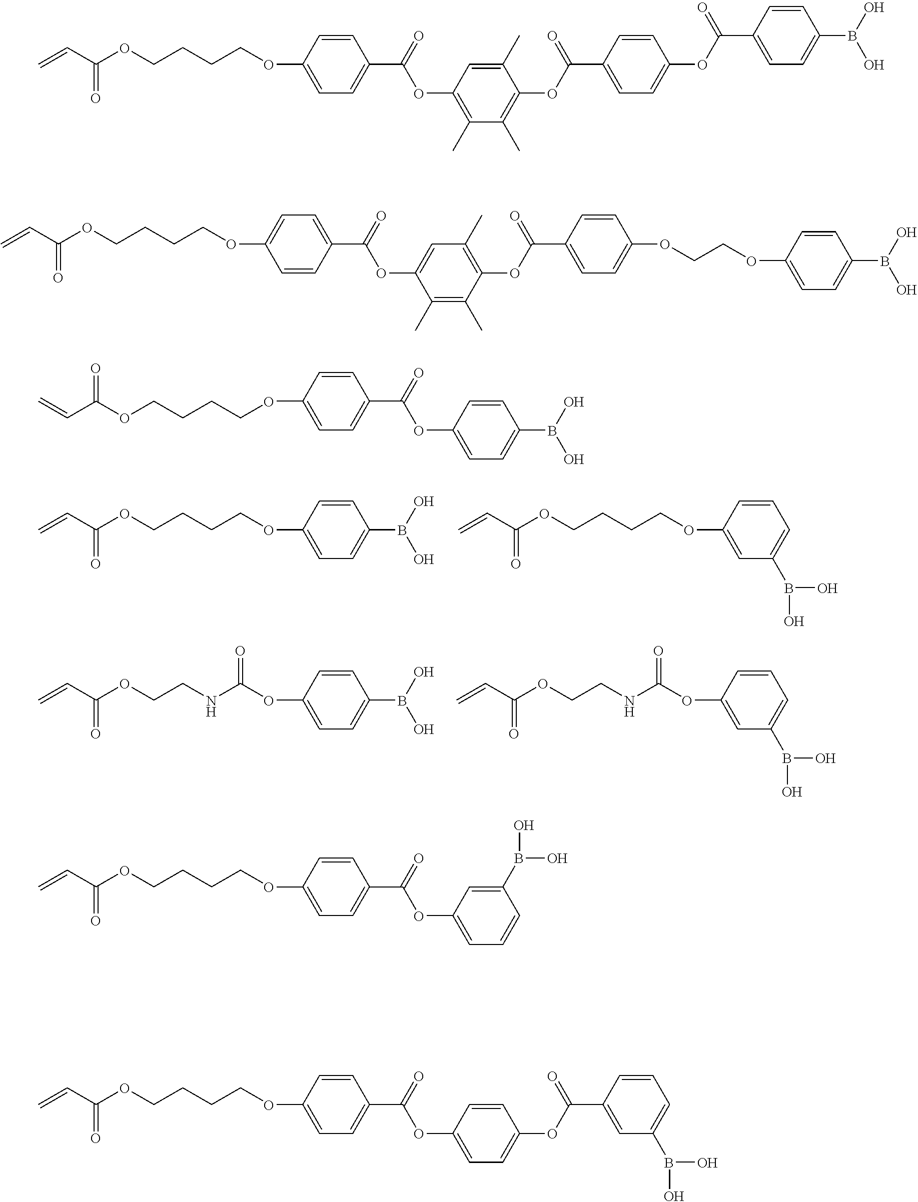

In a case where the liquid crystal composition contains a boronic acid monomer, a content of the boronic acid monomer is preferably 1% to 10% by mass, more preferably 1% to 9% by mass, and still more preferably 2% to 8% by mass with respect to the total solid content of the liquid crystal composition.

### (Solvent)

From the viewpoint of workability for forming a retardation film, it is preferable that the liquid crystal composition contains a solvent.

As the solvent, an organic solvent is preferable, and specific examples thereof include ketones (for example, acetone, 2-butanone, methyl ethyl ketone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, methanol, ethanol, isopropanol, butanol, and cyclohexanol), cellosolves (for example, methyl cellosolve, ethyl cellosolve, and propylene glycol monomethyl ether), cellosolve acetates (for example, propylene glycol monomethyl ether acetate), sulfoxides (for example, dimethyl sulfoxide), and amides (for example, dimethylformamide and dimethylacetamide), and these may be used alone or in combination of two or more kinds thereof.

From the viewpoint that coatability of the liquid crystal composition is improved, the content of the solvent is preferably 55% to 85% by mass and more preferably 60% to 80% by mass with respect to the total mass of the liquid crystal composition.

In a case of containing two or more kinds of solvents, the total content thereof is preferably within the above-described range.

### Other Components

The liquid crystal composition may contain other components in addition to the above-described components, and examples thereof include a polymerization initiator, a leveling agent, a surfactant, a tilt angle control agent, an alignment assistant, a plasticizer, and a crosslinking agent.

### <Forming Method>

Examples of a method of forming the liquid crystal layer (positive C-plate) include a method of vertically aligning the rod-like liquid crystal compound using the above-described liquid crystal composition and then immobilizing the rod-like liquid crystal compound by polymerization.

Here, a condition for the alignment state to be the vertical alignment is not particularly limited, but it is preferable to perform a heating treatment, and it is more preferable to perform a cooling treatment after the heating treatment. From the viewpoint of manufacturing suitability, a heating temperature in the heat treatment is preferably 10 °C to 250 °C, more preferably 50 °C to 200 °C, and still more preferably 65 °C to 150 °C. In addition, a heating time in the heating treatment is preferably 1 to 300 seconds and more preferably 1 to 120 seconds.

In addition, a temperature in the cooling treatment after the heat treatment is not particularly limited as long as it is lower than the heating temperature in the heat treatment, but is preferably room temperature (23 °C) to 80 °C.

In addition, conditions for the above-described polymerization are not particularly limited, but ultraviolet rays are preferably used in the polymerization by light irradiation. An irradiation amount is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm². In order to promote the polymerization reaction, the treatment may be performed under heating conditions.

In addition, the vertical alignment is also referred to as homeotropic alignment, and means alignment in which an angle between a surface (main surface) of the liquid crystal layer and a director of the rod-like liquid crystal compound is in a range of 70° to 90°, and the alignment in a range of 80° to 90° is preferable and the alignment in a range of 85° to 90° is more preferable.

In the present invention, from the viewpoint of suppressing the alignment unevenness (alignment defect) in the liquid crystal layer, a difference (hereinafter, also abbreviated as “ASP value”) between a solubility parameter of the polymer contained in the above-described polymer film (support) and a solubility parameter of the liquid crystal compound having the highest content in the above-described liquid crystal composition is preferably 8.8 or more and more preferably 9.5 or more. The upper limit value of the ASP value is not particularly limited, but is preferably 15.0 or less and more preferably 12.5 or less.

Here, the ΔSP value is intended to be a 6a value of an SP value calculated by the method of Hoy et al. (see “PROPERTIES OF POLYMERS (ED. 3)”, written by VAN KREVELEN, D. W., published by ELSEVIER (1990)).

In addition, the δa value can be calculated by Expression (X) using the SP values (δd, δp, and δh) calculated by the method of Hoy et al.

δa=(δd²+δp²+δh²)^{0.5} Expression (X)

According to the method of Hoy et al., the values of δd, δp, and δh can be calculated from a chemical structural formula of a compound to be obtained (that is, a structure of a repeating unit of the polymer and the liquid crystal compound), but in a case where the chemical structural formula is not known, the SP value can be obtained from the center coordinates of a sphere encompassing only the point of the dissolved solvent by examining the solubility of the compound in a solvent for which the SP value (SP_{d}, SPₚ, and SPₕ) is known.

In addition, in a case where the polymer is a copolymer having two or more kinds of repeating units, the SP values (δd, δp, and δh) are calculated by a structural formula in which a bonding portion of each repeating unit is replaced with a hydrogen atom, the ΔSP value with the above-described liquid crystal compound is obtained for each repeating unit, and a value obtained by averaging the ΔSP values in terms of the molar ratio of each repeating unit is adopted.

In addition, in a case where the polymer film contains two or more kinds of polymers, the SP value of the polymer is obtained by calculating the ΔSP value (δd, δp, and δh) of each polymer and averaging the ΔSP values in terms of the molar ratio of each polymer.

In addition, in a case where two or more kinds of liquid crystal compounds having the highest content are present among the liquid crystal compounds contained in the above-described liquid crystal composition (for example, in a case where two kinds of liquid crystal compounds having different structures are both present in an amount of 40% by mass), the requirement that the ΔSP value is 8.8 or more need only be satisfied in a relationship with at least one kind of liquid crystal compound among the liquid crystal compounds having the highest content.

In the present invention, from the reason that the occurrence of cracks (breakage) in the retardation film during high-temperature durability is suppressed (hereinafter, also referred to as “excellent crack resistance”), it is preferable that the polymer contained in the polymer film (support) satisfies Expression (1).

In addition, in Expression (1), the product (Nw×ΔSP(A)) of Nw and ΔSP(A) is more preferably 900 or more. The upper limit value of the product is not particularly limited, but is preferably 10,000 or less and more preferably 5,000 or less.

Nw×ΔSP(A)≥700 (1)

In Expression (1), Nw represents a weight-average degree of polymerization of the polymer contained in the polymer film.

In addition, ΔSP(A) represents a difference between a solubility parameter of the polymer contained in the polymer film and a solubility parameter of acetone.

Here, the weight-average degree of polymerization (Nw) in Expression (1) is a value calculated from “Mw/Mp” obtained by dividing a weight-average molecular weight (Mw) of the polymer contained in the polymer film by an average molecular weight (Mp) per repeating unit (unit) of the polymer contained in the polymer film.

In addition, the weight-average molecular weight (Mw) is a weight-average molecular weight measured by gel permeation chromatography (GPC) after dissolving the polymer contained in the polymer film in tetrahydrofuran.

In addition, in a case where the polymer contained in the polymer film contains two or more kinds of repeating units, the average molecular weight (Mp) is a value obtained by averaging the molecular weights of the respective repeating units in terms of molar ratio of the respective repeating units.

Further, in a case where the polymer film contains two or more kinds of polymers, a value obtained by averaging the weight-average degrees of polymerization calculated from the respective polymers in terms of the molar ratio of the respective polymers is adopted.

In addition, ΔSP(A) in Expression (1), that is, the difference between the solubility parameter of the polymer contained in the polymer film and the solubility parameter of acetone can be calculated by the method described in the section of ΔSP value.

### [Polarizing Plate]

The polarizing plate according to the embodiment of the present invention is a polarizing plate including the above-described retardation film according to the embodiment of the present invention and a polarizer.

In the polarizing plate according to the embodiment of the present invention, it is preferable that the polarizer, the liquid crystal layer included in the retardation film, and the support included in the retardation film are arranged in this order.

### [Polarizer]

The polarizer included in the polarizing plate according to the embodiment of the present invention is not particularly limited as long as the polarizer is a member having a function of converting light into specific linearly polarized light, and a known absorptive type polarizer and reflective type polarizer in the related art can be used.

An iodine-based polarizer, a dye-based polarizer using a dichroic dye, a polyene-based polarizer, or the like is used as the absorptive type polarizer.

The iodine-based polarizer and the dye-based polarizer include a coating type polarizer and a stretching type polarizer, and any one of these polarizers can be applied. However, a polarizer which is produced by allowing polyvinyl alcohol to adsorb iodine or a dichroic dye and performing stretching is preferable.

In addition, examples of a method of obtaining a polarizer by performing stretching and dyeing in a state of a laminated film in which a polyvinyl alcohol layer is formed on a substrate include methods disclosed in JP5048120B, JP5143918B, JP4691205B, JP4751481B, and JP4751486B, and known technologies related to these polarizers can be preferably used.

A polarizer in which thin films having different birefringence are laminated, a wire grid type polarizer, a polarizer in which a cholesteric liquid crystal having a selective reflection range and a ¼ wavelength plate are combined, or the like is used as the reflective type polarizer.

Among those, a polarizer containing a polyvinyl alcohol-based resin (polymers containing —CH₂—CHOH— as a repeating unit. Particularly at least one selected from the group consisting of polyvinyl alcohol and an ethylene-vinyl alcohol copolymer) is preferable from the viewpoint that adhesiveness is more excellent.

In the present invention, a thickness of the polarizer is not particularly limited, but is preferably 5 to 40 μm, more preferably 5 to 30 μm, and still more preferably 5 to 20 μm. With the above-described thickness, it is possible to reduce the thickness of a display device.

In the polarizing plate according to the embodiment of the present invention, it is preferable that the slow axis of the support of the retardation film is disposed to be orthogonal or parallel to the absorption axis of the polarizer, and it is more preferable that the slow axis of the support of the retardation film is disposed to be parallel to the absorption axis of the polarizer.

### [Polarizer Protective Film]

In the polarizing plate according to the embodiment of the present invention, the polarizer protective film may be disposed on the surface of the polarizer. The polarizer protective film may be arranged only on one surface of the polarizer (on the surface opposite to the retardation film side) or may be arranged on both surfaces of the polarizer.

The configuration of the polarizer protective film is not particularly limited, and may be, for example, a transparent support or a hard coat layer, or a laminate of the transparent support and the hard coat layer.

As the hard coat layer, a known layer can be used, and for example, a layer obtained by polymerizing and curing polyfunctional monomers may be used.

In addition, a known transparent support can be used as the transparent support, and for example, as a material forming the transparent support, a cellulose-based polymer typified by triacetyl cellulose (hereinafter referred to as cellulose acylate), a thermoplastic norbornene-based resin (ZEONEX or ZEONOR manufactured by Nippon Zeon Co., Ltd., ARTON manufactured by JSR Corporation, and the like), an acrylic resin, or a polyester-based resin can be used.

The thickness of the polarizer protective film is not particularly limited, but from the reason that the thickness of the polarizing plate can be reduced, is preferably 50 μm or less.

### [Pressure-Sensitive Adhesive Layer]

In the polarizing plate according to the embodiment of the present invention, a pressure-sensitive adhesive layer may be disposed between the retardation film (particularly, the liquid crystal layer) and the polarizer.

The pressure-sensitive adhesive layer used for lamination of the retardation film and the polarizer is, for example, a substance in which a ratio (tan δ=G″/G′) of loss elastic modulus G″ to storage elastic modulus G′ is 0.001 to 1.5, where G′ and G″ are measured with a dynamic viscoelastometer. Such a substance includes a so-called pressure sensitive adhesive or easily creepable substance. Examples of the pressure sensitive adhesive which can be used in the present invention include a polyvinyl alcohol-based pressure sensitive adhesive, but the pressure sensitive adhesive is not limited thereto.

### [Image Display Device]

The image display device according to the embodiment of the present invention is an image display device including the above-described polarizing plate according to the embodiment of the present invention.

A display element used in the image display device is not particularly limited, and examples thereof include a liquid crystal cell, an organic electroluminescence (hereinafter, simply referred to as “EL”) display panel, and a plasma display panel. Among these, a liquid crystal cell or an organic EL display panel is preferable, and a liquid crystal cell is more preferable.

That is, as the image display device, a liquid crystal display device using a liquid crystal cell as the display element or an organic EL display device using an organic EL display panel as the display element is preferable, and the liquid crystal display device is more preferable.

### [Liquid Crystal Display Device]

The liquid crystal display device which is an example of the image display device is a liquid crystal display device including the above-described polarizing plate according to the embodiment of the present invention and a liquid crystal cell of an in-plane switching mode, in which the polarizer included in the polarizing plate, the liquid crystal layer included in the polarizing plate, the support included in the polarizing plate, and the liquid crystal cell are arranged in this order from the viewing side.

Hereinafter, the liquid crystal cell constituting the liquid crystal display device will be described in detail.

### <Liquid Crystal Cell>

The liquid crystal cell used in the liquid crystal display device according to the embodiment of the present invention is preferably an in-plane switching (IPS) mode.

It is preferable that the liquid crystal cell used in the liquid crystal display device is in a vertical alignment (VA) mode, an optically compensated bend (OCB) mode, an in-plane-switching (IPS) mode, a fringe-field-switching (FFS) mode, or a twisted nematic (TN) mode, but is not limited thereto.

In the liquid crystal cell in a TN mode, rod-like liquid crystalline molecules are substantially horizontally aligned at the time of no voltage application and further twisted and aligned at 600 to 120°. The liquid crystal cell in a TN mode is most frequently used as a color thin film transistor (TFT) liquid crystal display device and is described in a plurality of documents.

In the liquid crystal cell in a VA mode, rod-like liquid crystalline molecules are substantially vertically aligned at the time of no voltage application. The concept of the liquid crystal cell in a VA mode includes (1) a liquid crystal cell in a VA mode in a narrow sense where rod-like liquid crystalline molecules are aligned substantially vertically at the time of no voltage application and substantially horizontally at the time of voltage application (described in JP1990-176625A (JP-H2-176625A)), (2) a liquid crystal cell (in an MVA mode) (SID97, described in Digest of tech. Papers (proceedings) 28 (1997) 845) in which the VA mode is formed to have multi-domain in order to expand the viewing angle, (3) a liquid crystal cell in a mode (n-ASM mode) in which rod-like liquid crystalline molecules are substantially vertically aligned at the time of no voltage application and twistedly multi-domain aligned at the time of voltage application (described in proceedings of Japanese Liquid Crystal Conference, pp. 58 to 59 (1998)), and (4) a liquid crystal cell in a SURVIVAL mode (presented at LCD International 98). In addition, the liquid crystal cell in the VA mode may be any of a patterned vertical alignment (PVA) type, an optical alignment type, or a polymer-sustained alignment (PSA). The details of these modes are described in JP2006-215326A and JP2008-538819A.

In an IPS mode liquid crystal cell, rod-like liquid crystal molecules are substantially aligned parallel to a substrate and application of an electric field parallel to a surface of the substrate causes the liquid crystal molecules to respond planarly. In the IPS mode, black display is carried out in a state where no electric field is applied, and absorption axes of a pair of upper and lower polarizing plates are orthogonal to each other. A method of reducing light leakage during black display in an oblique direction and improve the viewing angle using an optical compensation sheet is disclosed in JP1998-54982A(JP-H10-54982A), JP1999-202323A (JP-H11-202323A), JP1997-292522A(JP-H9-292522A), JP1999-133408A(JP-H11-133408A), JP1999-305217A (JP-H11-305217A), JP1998-307291A (JP-H10-307291A), and the like.

### [Organic EL Display Device]

Examples of an organic EL display device as an example of the image display device include an aspect in which the polarizing plate according to the embodiment of the present invention (a polarizing plate in which the polarizer is disposed on a viewing side) and an organic EL display panel are provided in this order from a viewing side.

In addition, the organic EL display panel is a display panel formed of an organic EL element obtained by sandwiching an organic light emitting layer (organic electroluminescence layer) between electrodes (between a cathode and an anode). The configuration of the organic EL display panel is not particularly limited, and a known configuration is employed.

### EXAMPLES

Hereinbelow, the present invention will be described in more detail with reference to Examples. The materials, amounts used, proportions, treatment contents, processing procedures, and the like shown in the following examples can be modified as appropriate in the range of not departing from the spirit of the present invention. Therefore, the scope of the present invention should not be restrictively interpreted by the following Examples.

### Example 1

### [Preparation of Resin Composition 1]

According to Examples of JP5119250B, 77.82 parts of 3,9-bis(2-hydroxy-1,1-dimethylethyl)-2,4,8,10-tetraoxaspiro[5.5]undecane (hereinafter, abbreviated as “SPG”), 54.43 parts of 9,9-bis(4-hydroxy-3-methylphenyl)fluorene (hereinafter, abbreviated as “BCF”), 89.29 parts of diphenyl carbonate, and 1.8×10⁻² parts of tetramethylammonium hydroxide and 1.6×10⁻⁴ parts of sodium hydroxide as a catalyst were used to prepare a resin composition 1. A molar ratio of the SPG part: the BCF part was 64:36.

### [Preparation of Support)

According to Examples of JP5119250B, the above-described resin composition 1 was formed into a film, and then uniaxially stretched in a length direction to obtain a support 1 (polymer film 1) having a width of 300 mm and a length of 300 μm.

A sample having a size of 50 mm×10 mm was cut out from a central portion of the obtained film, and a photoelastic constant was measured using a Spectroellipsometer M-220 (manufactured by JASCO Corporation) and a retardation was measured using AxoScan OPMF-1 (manufactured by Opto Science, Inc.) with the sample. The results are shown in Table 2 below. In Table 2 below, “Pos A” in the classification of the optical properties of the support represents a positive A plate.

### [Preparation of Liquid Crystal Composition I]

A liquid crystal composition I having the following formulation was prepared.

Liquid crystal composition I

| | |
|---|---|
| Liquid crystal compound R1 shown below | 10.00 parts by mass |
| Liquid crystal compound R2 shown below | 24.80 parts by mass |
| Liquid crystal compound R3 shown below | 24.80 parts by mass |
| Liquid crystal compound R4 shown below | 20.20 parts by mass |
| Liquid crystal compound R5 show below | 20.20 parts by mass |
| Liquid crystal compound A1 shown below | 10.10 parts by mass |
| Alignment assistant B1 shown below | 3.00 parts by mass |
| Compound C1 shown below | 8.00 parts by mass |
| Photopolymerization initiator S1 shown below | 3.00 parts by mass |
| Surfactant P1 shown below | 0.21 parts by mass |
| Cyclopentanone | 232.80 parts by mass |
| Methyl ethyl ketone | 60.50 parts by mass |
| Methanol | 9.10 parts by mass |

Liquid Crystal Compound R1 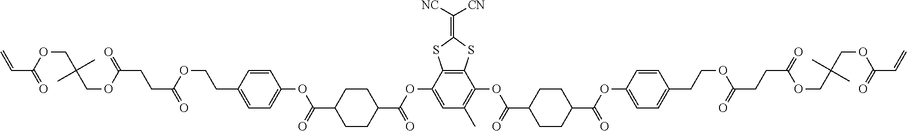 [SMILES: C=CC(=O)OCC(C)(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]
Liquid crystal compound R2 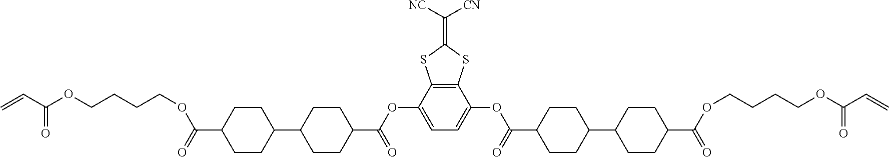 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Liquid crystal compound R3 (in the following formulae, t-Bu represents a tert-butyl group) 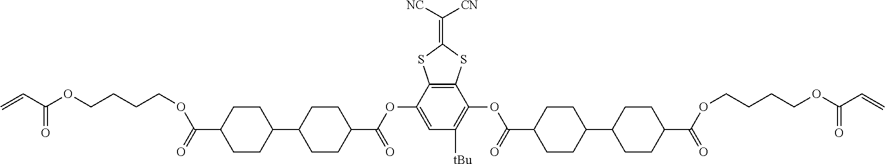 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Liquid crystal compound R4 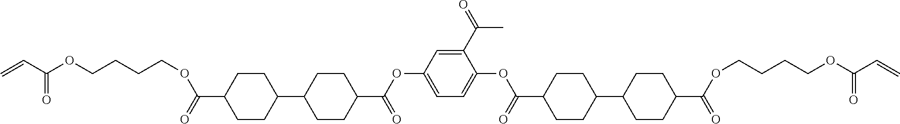 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c(C(C)=O)c3)CC2)CC1]
Liquid crystal compound R5 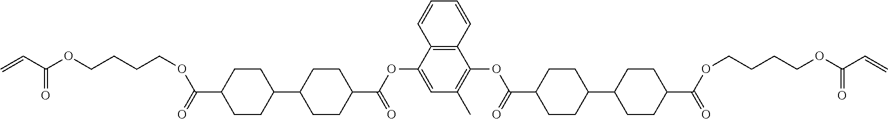 [SMILES: C=CC(=O)OCCCCOC(=O)C1CCC(C2CCC(C(=O)Oc3cc(C)c(OC(=O)C4CCC(C5CCC(C(=O)OCCCCOC(=O)C=C)CC5)CC4)c4ccccc34)CC2)CC1]
Liquid crystal compound A1 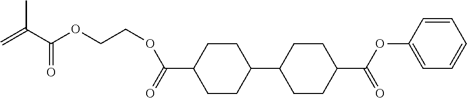 [SMILES: C=C(C)C(=O)OCCOC(=O)C1CCC(C2CCC(C(=O)Oc3ccccc3)CC2)CC1]
Compound B1 (alignment auxiliary agent) 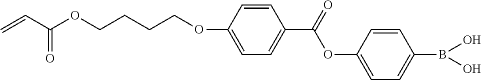 [SMILES: C=CC(=O)OCCCCOc1ccc(C(=O)Oc2ccc(B(O)O)cc2)cc1]
Compound C1 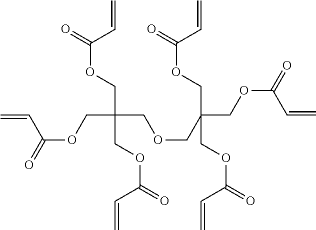 [SMILES: C=CC(=O)OCC(COCC(COC(=O)C=C)(COC(=O)C=C)COC(=O)C=C)(COC(=O)C=C)COC(=O)C=C]
Photopolymerization initiator S1 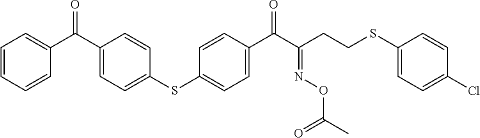 [SMILES: CC(=O)O/N=C(\CCSc1ccc(Cl)cc1)C(=O)c1ccc(Sc2ccc(C(=O)c3ccccc3)cc2)cc1]
Sufactant P1 [weight-average molecular weight: 11,200, numerical values in the following formulae indicate a content (% by mole) of each repeating unit with respect to all
repeating units]

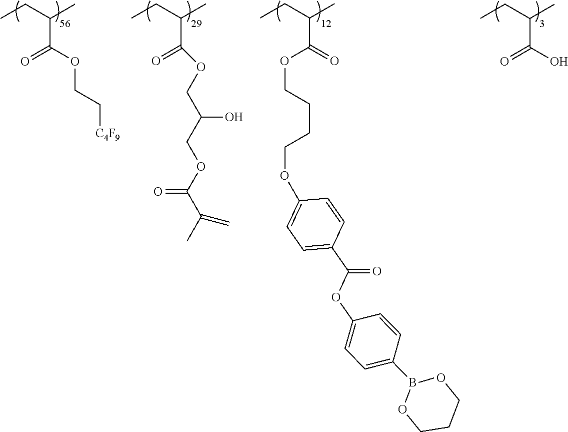

### [Production of Retardation Film L1]

A surface of the support 1 was subjected to a corona treatment at a discharge amount of 150 W·min/m², and the polymerizable liquid crystal composition 2-1 prepared in the following formulation was applied onto the corona-treated surface with a die coater to form a composition layer. Next, the composition was heated at 85 °C for 60 seconds for drying of the solvent of the composition and alignment aging of the liquid crystal compound. The vertical alignment state was fixed by irradiation with ultraviolet rays (150 mJ/cm²) at 60 °C in a nitrogen purge atmosphere with an oxygen concentration of 100 ppm, thereby producing a liquid crystal layer 2-1 having a thickness of 2.0 μm. In this way, the support 1 was continuously coated with the liquid crystal layer I for 300 μm to produce a long retardation film L1. In a case where a retardation of the produced retardation film L¹ was measured and a retardation of the support 1 measured in advance was subtracted to calculate a retardation of the liquid crystal layer I, it was confirmed that a thickness direction retardation RthC (550) was −90 nm, RthC (450)/RthC (550) was 0.88, and the liquid crystal layer I was a positive C-plate (nz>nx=ny).

### Example 2

### [Production of Retardation Film L2]

A retardation film L2 was produced in the same manner as in Example 1, except that a liquid crystal composition II having the following composition was used instead of the liquid crystal composition I.

Liquid crystal composition II

| | |
|---|---|
| Liquid crystal compound R6 shown below | 10.00 parts by mass |
| Liquid crystal compound R1 shown above | 54.00 parts by mass |
| Liquid crystal compound R7 shown below | 28.00 parts by mass |
| Liquid crystal compound T1 shown below | 8.00 parts by mass |
| Compound B1 (alignment auxiliary agent) shown above | 4.50 parts by mass |
| NK Ester A-600 (manufactured by Shin-Nakamura Chemical Co., Ltd.) | 12.00 parts by mass |
| Polymerization initiator S1 shown above | 1.50 parts by mass |
| Surfactant P1 shown above | 0.17 parts by mass |
| Methyl ethyl ketone | 225.00 parts by mass |
| Methanol | 25.00 parts by mass |

Liquid crystal compound R6 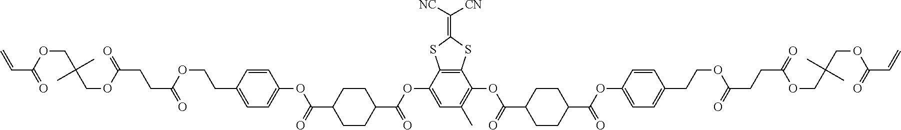 [SMILES: C=CC(=O)OCC(C)(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]
Liquid crystal compound R7 [mixture of the following liquid crystal compounds (RA), (RB), and (RC) at a mass ratio of 83:15:2; Me in the following liquid crystal
compounds (RB) and (RC) represents a methyl group]
(RA) 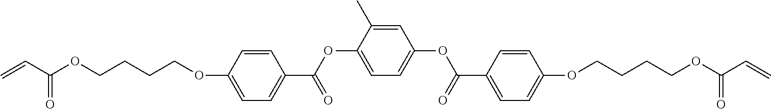 [SMILES: C=CC(=O)OCCCCOc1ccc(C(=O)Oc2ccc(OC(=O)c3ccc(OCCCCOC(=O)C=C)cc3)c(C)c2)cc1]
(RB) 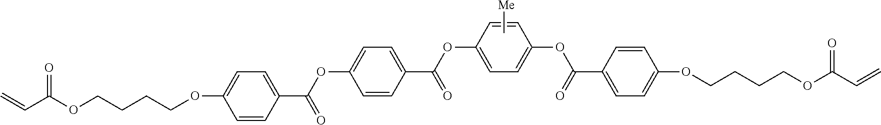
(RC) 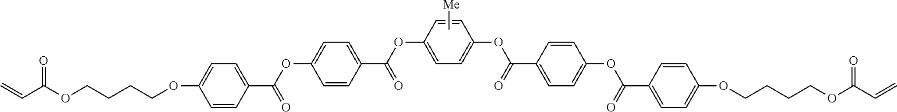
Liquid Crystal Compound L1

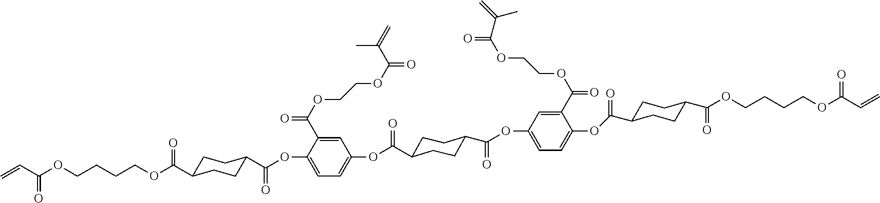 [SMILES: C=CC(=O)OCCCCOC(=O)C1CCC(C(=O)Oc2ccc(OC(=O)C3CCC(C(=O)Oc4ccc(OC(=O)C5CCC(C(=O)OCCCCOC(=O)C=C)CC5)c(C(=O)OCCOC(=O)C(=C)C)c4)CC3)cc2C(=O)OCCOC(=O)C(=C)C)CC1]

In a case where a retardation of the prepared retardation film L2 was measured and a retardation of the support 1 measured in advance was subtracted to calculate a retardation of the liquid crystal layer II, it was found that a thickness direction retardation RthC (550) was −101 nm, RthC (450)/RthC (550) was 0.95, and the liquid crystal layer II was a positive C-plate (nz>nx=ny).

### Example 3

### [Production of Retardation Film L3]

A retardation film L3 was produced by the same method as in Example 2, except that the molar ratio of SPG:BCF in the resin composition 1 was changed to 50:50.

### Example 4

### [Preparation of Resin Composition 2]

1.90 mol of BCF and 1.90 mol of 1,4-cyclohexanedicarboxylic acid dimethyl (CHD) were added with 2×10⁻⁴ mol of manganese acetate tetrahydrate and 8×10⁻⁴ mol of calcium acetate monohydrate as an ester exchange catalyst, and the mixture was gradually heated and melted while being stirred.

Next, the temperature was raised to 230 °C, 14×10⁻⁴ mol of trimethyl phosphate and 20×10⁻⁴ mol of germanium oxide were added thereto, and methanol as a by-product was removed by gradually raising the temperature to 270 °C and reducing the pressure to 0.13 kPa or less.

Next, the stirring was stopped, and the contents were taken out from the reactor to prepare a resin composition. The molar ratio of the BCF part: the CHD part was 50:50.

### [Production of Retardation Film L4]

A retardation film L4 was produced by the same method as in Example 1, except that the above-described resin composition 2 was used instead of the resin composition 1.

### Example 5

### [Production of Retardation Film L5]

A retardation film L5 was produced by the same method as in Example 4, except that the above-described liquid crystal composition II was used instead of the liquid crystal composition I.

### Example 6

### [Production of Retardation Film L6]

A retardation film L6 was produced by the same method as in Example 5, except that BCF in the resin composition 2 was changed to 9,9-bis[4-(2-hydroxyethoxy)phenyl]fluorene (hereinafter, abbreviated as “BPEF”).

### Example 7

### [Manufacture of Retardation Film L7]

A retardation film L7 was produced by the same method as in Example 5, except that BCF in the resin composition 2 was changed to 9,9-bis(4-hydroxyphenyl)fluorene (hereinafter, abbreviated as “BPF”).

### [Example 8][Manufacture of Retardation Film L8]

A retardation film L8 was produced by the same method as in Example 5, except that BCF in the resin composition 2 was changed to bis(9-hydroxymethylfluorene-9-yl)methane (hereinafter, abbreviated as “BHIM”).

### [Example 9][Manufacture of Retardation Film L9]

A retardation film L9 was produced by the same method as in Example 5, except that BCF in the resin composition 2 was changed to bis[9-(3-hydroxypropyl)-fluorene-9-yl]methane (hereinafter, abbreviated as “BHPIM”).

### [Example 10][Manufacture of Retardation Film L10]

A retardation film L10 was produced by the same method as in Example 2, except that BCF in the resin composition 1 was changed to BHIM.

### [Example 11][Manufacture of Retardation Film L11]

A retardation film L11 was produced by the same method as in Example 2, except that BCF in the resin composition 1 was changed to 6,6′-dihydroxy-3,3,3′,3′-tetramethyl-1,1′-spirobiindane (hereinafter, abbreviated as “SBI”).

### Example 12

### [Production of Retardation Film L12]

A retardation film L12 was produced by the same method as in Example 1, except that a liquid crystal composition III having the following composition was used instead of the liquid crystal composition I.

Liquid crystal composition III

| | |
|---|---|
| Liquid crystal compound R7 shown above | 100.0 parts by mass |
| Compound B1 shown above (alignment assistant) | 4.5 parts by mass |
| Alignment assistant A1 shown below | 2.0 parts by mass |
| A-TMMT (manufactured by Shin-Nakamura Chemical Co., Ltd.) | 8.0 parts by mass |
| Photopolymerization initiator S2 shown below | 5.0 parts by mass |
| Photopolymerization initiator S3 shown below | 2.0 parts by mass |
| Surfactant P2 shown below | 0.4 parts by mass |
| Surfactant P1 shown above | 0.5 parts by mass |
| Acetone | 353.0 parts by mass |
| Propylene glycol monomethyl ether acetate | 122.0 parts by mass |
| Methanol | 15.0 parts by mass |

Alignment assistant A1 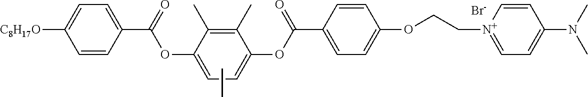
Photopolymerization initiator S2 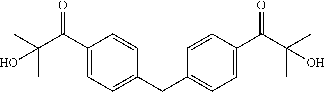 [SMILES: CC(C)(O)C(=O)c1ccc(Cc2ccc(C(=O)C(C)(C)O)cc2)cc1]
Photopolymerization initiator S3 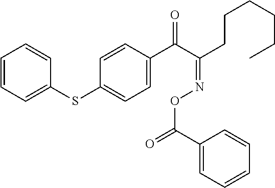 [SMILES: CCCCCC/C(=N/OC(=O)c1ccccc1)C(=O)c1ccc(Sc2ccccc2)cc1]
Surfactant P2 [weight-average molecular weight: 15,000, in the following formula, a numerical value attached to
a parenthesis of a repeating unit means % by mass]

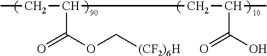

### Example 13

### [Production of Retardation Film L13]

A retardation film L13 was produced in the same manner as in Example 2, except that the film was biaxially stretched in the length direction and the width direction. In Table 2 below, “Neg B” in the classification of the optical properties of the support represents a negative B plate (nx>nz>ny).

### Example 14

### [Production of Retardation Film L14]

A retardation film L14 was produced in the same manner as in Example 4, except that the above-described liquid crystal composition III was used instead of the liquid crystal composition I.

### Example 15

### [Production of Retardation Film L15]

A retardation film L15 was produced in the same manner as in Example 1, except that the following liquid crystal composition IV was used instead of the liquid crystal composition I.

Liquid Crystal Composition IV

Liquid crystal compound R6 shown above 10.00 parts by mass
Liquid crystal compound R1 shown above 54.00 parts by mass
Liquid crystal compound R7 shown above 28.00 parts by mass
Liquid crystal compound T1 shown above 8.00 parts by mass
NK Ester A-600 (manufactured by Shin-Nakamura Chemical Co.,
Ltd.) 12.00 parts by mass
Polymerization initiator S1 shown above 1.50 parts by mass
Surfactant P1 shown above 0.17 parts by mass
Methyl ethyl ketone 225.00 parts by mass
Methanol 25.00 parts by mass

### Example 16

### [Production of Retardation Film L16]

A retardation film L16 was produced in the same manner as in Example 2, except that the molar ratio of SPG:BCF in the resin composition 1 was changed to 20:80.

### Example 17

### [Production of Retardation Film L17]

A retardation film L17 was produced in the same manner as in Example 2, except that isosorbide (hereinafter, abbreviated as “ISB”) was used instead of SPG in the resin composition 1, and the resin composition was prepared such that the molar ratio of the ISB part and the BCF part was ISB:BCF=50:50.

### Example 18

### [Production of Retardation Film L18]

A retardation film L18 was produced in the same manner as in Example 17, except that the above-described liquid crystal composition III was used instead of the liquid crystal composition II.

### Example 19

### [Production of Retardation Film L19]

A retardation film L19 was produced in the same manner as in Example 2, except that the following liquid crystal composition IV was used instead of the liquid crystal composition II.

Liquid Crystal Composition IV

| | |
|---|---|
| Liquid crystal compound R8 shown below | 100.00 parts by mass |
| Compound B1 (alignment auxiliary agent) shown above | 4.50 parts by mass |
| NK Ester A-600 (manufactured by Shin-Nakamura Chemical Co., Ltd.) | 12.00 parts by mass |
| Polymerization initiator S1 shown above | 1.50 parts by mass |
| Surfactant P2-1 shown above | 0.17 parts by mass |
| Methyl ethyl ketone | 225.00 parts by mass |
| Methanol | 25.00 parts by mass |

Liquid crystal compound R8

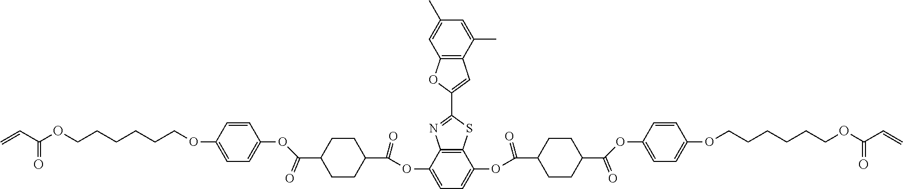 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]

### Example 20

### [Production of Retardation Film L20]

A retardation film L20 was produced by the same method as in Example 5, except that the above-described liquid crystal composition IV was used instead of the liquid crystal composition II.

### Example 21

### [Preparation of Resin Composition 21]

A resin composition 21 was prepared such that the molar ratio of the SPG part to the BCF part was 64:36 according to Examples of JP3995387B.

### [Production of Retardation Film L21]

A retardation film L21 was produced by the same method as in Example 2, except that the resin composition 21 was used instead of the resin composition 1.

### Example 22

### [Production of Retardation Film L22]

A retardation film L22 was produced by the same method as in Example 4, except that the weight average degree of polymerization of the resin composition 2 was adjusted to 180.

### Example 23

### [Production of Retardation Film L23]

A retardation film L23 was produced by the same method as in Example 16, except that the thickness of the support was adjusted to 45 μm.

### Example 24

A retardation film L24 was produced by the same method as in Example 2, except that the thickness of the support was adjusted to 120 μm.

### Example 25

A retardation film L25 was produced by the same method as in Example 22, except that the thickness of the support was adjusted to 30 μm.

### Example 26

### [Production of Retardation Film L26]

A resin film used in Example 1 of JP2023-180135A was monoaxially stretched in a length direction to produce a support having a width of 300 mm and a length of 300 μm.

A retardation film L26 was produced by the same method as in Example 1, except that the support produced above was used instead of the support 1 (polymer film 1). Each material constituting the resin film is denoted by the following abbreviations.
Ethyl cellulose (“ETHOCEL standard 100” manufactured by Dow Chemical Company): ETHOCEL
9-Vinylcarbazole: BCA
α-Cyano-4-hydroxycinnamic acid isobutyl: CHI
Isobutyl acrylate: AI

### Example 27

### [Production of Retardation Film L27]

A retardation film L27 was produced by the same method as in Example 26, except that a liquid crystal composition II was used instead of the liquid crystal composition I.

### Comparative Example 1

### [Production of Retardation Film H1]

A retardation film H1 was produced by the same method as in Example 1, except that bisphenol A (hereinafter, abbreviated as “BPA”) was used instead of SPG in the resin composition 1, and the resin composition was prepared such that the molar ratio of the BPA part and the BCF part was BPA:BCF=33:67.

### Comparative Example 2

### [Production of Retardation Film H2]

A retardation film H2 was produced by the same method as in Comparative Example 1, except that the above-described liquid crystal composition II was used instead of the liquid crystal composition I.

### Comparative Example 3

### [Production of Retardation Film H3]

A retardation film H3 was produced by the same method as in Comparative Example 1, except that the above-described liquid crystal composition III was used instead of the liquid crystal composition I.

### Comparative Example 4

### [Production of Retardation Film H4]

A retardation film H4 was produced by the same method as in Example 2, except that a polycarbonate film [product name: Pure-Ace (manufactured by Teijin Limited.), Rel (550)=154 nm, Rth1 (550)=77 nm, film thickness: 76 μm] used in Example 1 of WO2020/045224A was used as a substrate.

### [Production of Liquid Crystal Display Device for Evaluating Display Performance]

### [Production of Protective Film 1]

### [Preparation of Core Layer Cellulose Acylate Dope 1]

The following composition was put into a mixing tank and stirred to dissolve the respective components, thereby preparing a core layer cellulose acylate dope 1.

Core layer cellulose acylate dope 1

| | |
|---|---|
| Cellulose acetate having acetyl substitution | 100 parts by mass |
| degree of 2.88 | |
| Ester oligomer (the following compound 1-1) | 10 parts by mass |
| Durability improver (the following compound 1-2) | 4 parts by mass |
| Ultraviolet absorber (the following compound 1-3) | 3 parts by mass |
| Methylene chloride (first solvent) | 438 parts by mass |
| Methanol (second solvent) | 65 parts by mass |

Compound 1-1 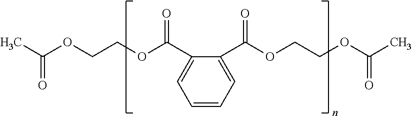
Compound 1-2 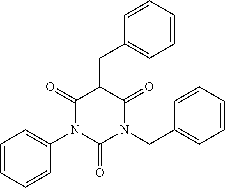 [SMILES: O=C1C(Cc2ccccc2)C(=O)N(c2ccccc2)C(=O)N1Cc1ccccc1]
Compound 1-3

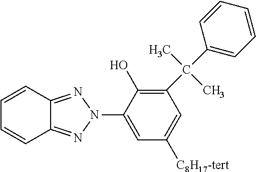

### <Preparation of Outer Layer Cellulose Acylate Dope 1>

10 parts by mass of the following matting agent dispersion liquid 1 was added to 90 parts by mass of the above-described core layer cellulose acylate dope 1, thereby preparing an outer layer cellulose acylate dope 1.

Matting agent solution

Silica particles with average particle size of 20 nm
(AEROSIL R972, manufactured by Nippon Aerosil Co., Ltd.):
2 parts by mass
Methylene chloride (first solvent) 76 parts by mass
Methanol (second solvent) 11 parts by mass
Core layer cellulose acylate dope 1 1 part by mass

### <Production of Protective Film 1>

Three layers of the above-described core layer cellulose acylate dope 1 and the outer layer cellulose acylate dopes 1 on both sides thereof were simultaneously cast from a casting port onto a drum at 20 °C. In a state in which the content of the solvent in the film on the drum was approximately 20% by mass, the film was peeled off from the drum, and both ends of the obtained film in a width direction were fixed with tenter clips, and in a state in which the content of the residual solvent in the film was 3% to 15% by mass, the film was stretched 1.2 times in the transverse direction and dried. Thereafter, the obtained film was transported between rolls of a heat treatment device to produce a cellulose acylate film 1 having a thickness of 25 μm, which was used as a protective film 1.

[Production of Protective Film 1 with Hard Coat Layer]

As a coating liquid for forming a hard coat layer, a curable composition (hard coat 1) for a hard coat, shown in the following table, was prepared.

TABLE 1

| | Monomer | | | | | | |
|---|---|---|---|---|---|---|---|
| | | | | Total | UV initiator | | |
| | | | | added | | added | |
| | | | | amount | | amount | |
| | | | Monomer 1/ | [parts by | | [parts by | |
| | Monomer 1 | Monomer 2 | Monomer 2 | mass] | Type | mass] | Solvent |
| Hard | Pentaerythritol | Pentaerythritol | 3/2 | 53.5 | UV | 1.5 | Ethyl |
| coat 1 | triacrylate | tetraacrylate | | | initiator 1 | | acetate |

In Table 1, the structure of the ultraviolet (UV) initiator 1 is shown below.

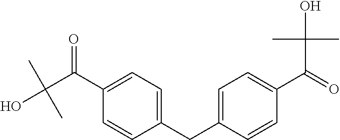 [SMILES: CC(C)(O)C(=O)c1ccc(Cc2ccc(C(=O)C(C)(C)O)cc2)cc1]

The above-described curable composition for a hard coat was applied onto a surface of the protective film 1 produced as described above, dried at 100 °C for 60 seconds, and cured by being irradiated with UV at 1.5 kW and 300 mJ under the conditions of 0.1% or less of nitrogen to produce a protective film 1 with a hard coat layer, having a hard coat layer with a film thickness of 5 μm. The film thickness of the hard coat layer was adjusted by adjusting a coating amount by a die coating method using a slot die.

[Production of Polarizing Plate 1 with Protective Film on One Side]

### (1) Saponification of Film

The produced protective film 1 with a hard coat layer was immersed for 1 minute in a 4.5 mol/L sodium hydroxide aqueous solution (saponified solution) in which a temperature was adjusted to 37 °C, washed with water, immersed in a 0.05 mol/L sulfuric acid aqueous solution for 30 seconds, and further passed through a water washing bath. The obtained film was repeatedly dehydrated three times with an air knife to drop water, and then dried by leaving it in a drying zone at 70 °C for 15 seconds to produce a saponified protective film 1 with a hard coat layer.

### (2) Production of Polarizer

According to Examples of JP2016-148724A, a polarizer with a film thickness of 15 m was prepared by imparting a difference in circumferential speed between two pairs of nip rolls and stretching in the longitudinal direction. The polarizer thus produced was used as a polarizer 1.

### (3) Bonding

The polarizer 1 thus obtained and the saponified protective film 1 with a hard coat layer were bonded to each other in a roll-to-roll manner so that the polarizing axis and the longitudinal direction of the film were orthogonal to each other, using a 3% PVA (manufactured by Kuraray Co., Ltd., PVA-117H) aqueous solution as an adhesive, thereby producing a polarizing plate 1 with a protective film on one side (hereinafter also simply referred to as “polarizing plate 1”). In this case, the bonding was carried out such that the cellulose acylate film side of the protective film was on the polarizer side.

### [Production of First Polarizing Plate]

The liquid crystal layer of each of the retardation films produced in Examples and Comparative Examples and the polarizer surface of the polarizing plate 1 were bonded to each other in a roll-to-roll manner using a 3% aqueous solution of PVA (PVA-117H, manufactured by Kuraray Co., Ltd.) as an adhesive such that the polarizing axis and the longitudinal direction of the film were orthogonal to each other, thereby producing a first polarizing plate.

### [Production of Protective Film 2]

### <Production of Polymethyl Methacrylate (PMMA) Dope>

The following dope composition was put into a mixing tank and stirred to dissolve each component, thereby preparing a PMMA dope.

PMMA dope

PMMA resin 100 parts by mass
SUMILIZER GS (manufactured by Sumitomo Chemical Co.,
Ltd.) 0.1 parts by mass
Dichloromethane 426 parts by mass
Methanol 64 parts by mass

### <Production of Protective Film 2>

The above-described PMMA dope was uniformly cast on a stainless steel band (casting support) from a casting die (band casting machine). The film was peeled off in a state in which the content of the solvent in the cast film was approximately 20% by mass, and both ends of the film in a width direction were fixed with tenter clips and dried while the film was stretched at a stretching ratio of 1.1 times in the transverse direction. Thereafter, the obtained film was transported between rolls of a heat treatment device and further dried to produce a PMMA film with a film thickness of 20 μm, which was used as a protective film 2.

### [Production of Second Polarizing Plate]

### <Preparation of Adhesive Composition 1>

The following compounds were mixed at described ratios to produce an adhesive composition 1.
Polymerizable compound (ARONIX M-220, manufactured by Toagosei Co., Ltd.): 20 parts by mass
Polymerizable compound (4-Hydroxybutyl acrylate, manufactured by Nihon Kasei CO., LTD.): 40 parts by mass
Polymerizable compound (2-Ethylhexyl acrylate, manufactured by Mitsubishi Chemical Corporation): 40 parts by mass
Polymerizable initiator (Irgacure 907, manufactured by BASF SE): 1.5 parts by mass
Sensitizer (KAYACURE DETX-S, manufactured by Nippon Kayaku Co., Ltd.): 0.5 parts by mass

### <Production of Second Polarizing Plate>

A polarizer-bonded surface of the protective film 2 was subjected to a corona treatment with a discharge amount of 150 W-min/m², and then the adhesive composition 1 was coated so as to have a film thickness of 0.5 μm.

Thereafter, the adhesive-coated surface was bonded to the polarizer surface of the polarizing plate 1 with a protective film on one side, and irradiated with ultraviolet rays from the support side of the protective film 2 at 300 mJ/cm² at 40 °C in an air atmosphere. Subsequently, the resultant was dried at 60 °C for 3 minutes to produce a second polarizing plate.

### [Production of Liquid Crystal Display Device]

The polarizing plates on the front and back of a commercially available liquid crystal display device (iPad (registered trademark), manufactured by Apple Inc.) (liquid crystal display device including a liquid crystal cell in FFS mode) were peeled off, and the first polarizing plate including each of the retardation films produced in Examples and Comparative Examples was bonded to the viewing side, and the second polarizing plate was bonded to the backlight side with a 20 μm acrylic pressure-sensitive adhesive such that the absorption axes of the polarizers in the respective polarizing plates were orthogonal to each other and the alignment direction of the liquid crystal in the liquid crystal cell was orthogonal to the absorption axis of the polarizer in the first polarizing plate, and a liquid crystal display device for evaluating the display performance of each of the retardation films produced in Examples and Comparative Examples was produced.

The liquid crystal cell in the liquid crystal display device included a color filter layer on the substrate on the first polarizing plate side and a TFT layer on the substrate on the second polarizing plate side, and Rth(550) of both the layers were 10 nm and 2 nm, respectively. In addition, Δn·d of the liquid crystal compound in the liquid crystal cell was 340, and a tilt angle of the liquid crystal compound with respect to the substrate surface was 0.1°.

### [Evaluation of Mounting Unevenness]

The produced liquid crystal display device was set to black display in a dark room, and in a case where the liquid crystal display device was visually observed at a polar angle of 60° for one cycle of the azimuthal angle, the evaluation was performed according to the following standard.

### <Evaluation Standard>

A: neither light leakage nor unevenness in tint was visually recognized.
B: light leakage and unevenness in tint were visually recognized, but the area thereof was 50% or less of the entire area.
C: light leakage and unevenness in tint were visually recognized in an area of 50% or more of the entire area.

### [Evaluation of Oblique Light Leakage]

The produced liquid crystal display device was set to black display in a dark room, and the black brightness was measured using a measuring machine (EZ-Contrast XL88, manufactured by ELDIM). With an average value of the brightness at azimuth angles of 45°, 135°, 225°, and 3150 at a polar angle of 60° defined as a light leak Y, evaluation was performed according to the following standard. With regard to the azimuth angle, the azimuthal angle was defined such that an absorption axis direction of the polarizer on the viewing side (first polarizer) is 0° (and 180°) and an absorption axis direction of the polarizer on the backlight side (second polarizer) is 900 (and 270°).

### <Evaluation Standard>

A: Y<0.6 (cd/m²)
B: 0.6 (cd/m²)≤Y<0.8 (cd/m²)
C: 0.8 (cd/m²)≤Y

### [Alignment Unevenness]

The 300 μm end portion of the elongated retardation film produced in Examples and Comparative Examples was cut into a length of 1,000 mm and a width of 1,340 mm. The film was set in the cross nicol with a film longitudinal direction aligned with one of polarizer absorption axes, and the observation was carried out from the polar angle 0° direction with the axis perpendicular to the film surface as a reference. An alignment failure rate (light leakage portion) visually recognized in this case was evaluated according to the following standard.

### <Evaluation Standard>

A: number of bright points (ink laydown) visually recognized in the observation part was less than 10.
B: the number of bright points (ink laydown) visually recognized in the observation part was 10 or more and less than 100.
C: the number of bright points (ink laydown) visually recognized in the observation part was 100 or more.

### [Adhesiveness]

The adhesiveness between the liquid crystal layer and the support in the retardation film produced in Examples and Comparative Examples was evaluated by performing a cross-cut test defined in JIS K 5600-5-6, and the peelability from the support at that time was evaluated according to the following standard.

### <Evaluation Standard>

A: area where the liquid crystal layer was peeled off was less than 1%.
B: area where the liquid crystal layer was peeled off was 1% or more and less than 50%.
C: area where the liquid crystal layer was peeled off was 50% or more.

### [Crack Resistance]

The first polarizing plate produced in Examples and Comparative Examples was cut into MD 260 mm×TD 80 mm, and the retardation film side was bonded to glass with a pressure sensitive adhesive SK-2057 (manufactured by Soken Chemical & Engineering Co., Ltd.).

The bonded sample was heated in an oven at 125 °C for 72 hours, and then left in a room at 25 °C and 60% for 300 hours, and then the occurrence of breakage (crack) was evaluated according to the following standard.

### <Evaluation Standard>

A: Cracks having a length of 1 mm or more did not occur in the plane.
B: 1 to 20 cracks having a length of 1 mm or more occurred in the plane.
C: 21 or more cracks having a length of 1 mm or more occurred in the plane.

For the long retardation films produced in Examples and Comparative Examples, the monomer compounds (two kinds) contained in the resin composition used for forming the support, the bond type and the average degree of polymerization during copolymerization, the optical characteristics of the support, the thickness, the main liquid crystal compound (the liquid crystal compound having the maximum content) contained in the liquid crystal composition used for forming the liquid crystal layer (the positive C-plate), the optical characteristics of the liquid crystal layer, the ΔSP value, ΔSP(A), the value of Expression (1) described above, and the product of the photoelastic constant (unit: Pa) and the thickness (unit: μm) are shown in Table 2 and Table 3.

TABLE 2

| | Resin composition | | | | | | | |
|---|---|---|---|---|---|---|---|---|
| | Monomer | | Monomer | | Monomer | | | Average |
| | compound 1 | | compound 2 | | compound 3 | | | degree of |
| | | Molar | | Molar | | Molar | Bond | polymerization |
| | Structure | ratio | Structure | ratio | Structure | ratio | Kind | Nw |
| Example 1 | BCF | 36 | SPG | 64 | — | — | Carbonate | 90 |
| Example 2 | BCF | 36 | SPG | 64 | — | — | Carbonate | 90 |
| Example 3 | BCF | 50 | SPG | 50 | — | — | Carbonate | 90 |
| Example 4 | BCF | 50 | CHD | 50 | — | — | Ester | 102 |
| Example 5 | BCF | 50 | CHD | 50 | — | — | Ester | 102 |
| Example 6 | BPEF | 50 | CHD | 50 | — | — | Ester | 106 |
| Example 7 | BPF | 50 | CHD | 50 | — | — | Ester | 108 |
| Example 8 | BHIM | 50 | CHD | 50 | — | — | Ester | 115 |
| Example 9 | BHPIM | 50 | CHD | 50 | — | — | Ester | 105 |
| Example 10 | BHIM | 36 | SPG | 64 | — | — | Carbonate | 88 |
| Example 11 | SBI | 36 | SPG | 64 | — | — | Carbonate | 95 |
| Example 12 | BCF | 36 | SPG | 64 | — | — | Carbonate | 90 |
| Example 13 | BCF | 36 | SPG | 64 | — | — | Carbonate | 90 |
| Example 14 | BCF | 50 | CHD | 50 | — | — | Ester | 102 |
| Example 15 | BCF | 36 | SPG | 64 | — | — | Carbonate | 90 |
| Example 16 | BCF | 80 | SPG | 20 | — | — | Carbonate | 92 |
| Example 17 | BCF | 50 | ISB | 50 | — | — | Carbonate | 94 |
| Example 18 | BCF | 50 | ISB | 50 | — | — | Carbonate | 94 |
| Example 19 | BCF | 36 | SPG | 64 | — | — | Carbonate | 90 |
| Example 20 | BCF | 50 | CHD | 50 | — | — | Ester | 102 |
| Example 21 | BCF | 36 | SPG | 64 | — | — | Carbonate | 110 |
| Example 22 | BCF | 50 | CHD | 50 | — | — | Ester | 180 |
| Example 23 | BCF | 80 | SPG | 20 | — | — | Carbonate | 92 |
| Example 24 | BCF | 36 | SPG | 64 | — | — | Carbonate | 90 |
| Example 25 | BCF | 50 | CHD | 50 | — | — | Ester | 180 |
| Example 26 | ETHOCEL | 100 | — | — | — | — | Glycoside | 520 |
| | BCA | 50 | CHI | 25 | AI | 25 | C—C | 500 |
| Example 27 | ETHOCEL | 100 | — | — | — | — | Glycoside | 520 |
| | BCA | 50 | CHI | 25 | AI | 25 | C—C | 500 |
| Comparative | BCF | 67 | BPA | 33 | — | — | Carbonate | 180 |
| Example 1 | | | | | | | | |
| Comparative | BCF | 67 | BPA | 33 | — | — | Carbonate | 180 |
| Example 2 | | | | | | | | |
| Comparative | BCF | 67 | BPA | 33 | — | — | Carbonate | 180 |
| Example 3 | | | | | | | | |
| Comparative | Pure-Ace (manufactured by Teijin Limited.) | | | | | | | |
| Example 4 | | | | | | | | |
| | Resin | Optical characteristics of support and the like | | | | | | |
| | composition | | | | | Re | | |
| | Mixing | | Re | Re | Rth | (450)/ | Photoelastic | |
| | ratio | | (450) | (550) | (550) | Re | constant | Thickness |
| | (mol %) | Classification | (nm) | (nm) | (nm) | (550) | (×10⁻¹² Pa) | (μm) |
| Example 1 | 100 | Pos A | 112 | 130 | 65 | 0.86 | 15 | 55 |
| Example 2 | 100 | Pos A | 112 | 130 | 65 | 0.86 | 15 | 55 |
| Example 3 | 100 | Pos A | 105 | 130 | 65 | 0.81 | 18 | 55 |
| Example 4 | 100 | Pos A | 107 | 130 | 65 | 0.83 | 22 | 55 |
| Example 5 | 100 | Pos A | 107 | 130 | 65 | 0.82 | 22 | 55 |
| Example 6 | 100 | Pos A | 112 | 130 | 65 | 0.86 | 22 | 55 |
| Example 7 | 100 | Pos A | 112 | 130 | 65 | 0.86 | 22 | 55 |
| Example 8 | 100 | Pos A | 107 | 130 | 65 | 0.82 | 22 | 55 |
| Example 9 | 100 | Pos A | 107 | 130 | 65 | 0.82 | 22 | 55 |
| Example 10 | 100 | Pos A | 114 | 130 | 65 | 0.88 | 15 | 55 |
| Example 11 | 100 | Pos A | 117 | 130 | 65 | 0.90 | 13 | 55 |
| Example 12 | 100 | Pos A | 112 | 130 | 65 | 0.86 | 15 | 55 |
| Example 13 | 100 | Neg A | 112 | 130 | 100 | 0.86 | 15 | 55 |
| Example 14 | 100 | Pos A | 108 | 130 | 65 | 0.83 | 22 | 55 |
| Example 15 | 100 | Pos A | 112 | 130 | 65 | 0.86 | 15 | 55 |
| Example 16 | 100 | Pos A | 112 | 130 | 65 | 0.86 | 30 | 55 |
| Example 17 | 100 | Pos A | 117 | 130 | 65 | 0.90 | 18 | 55 |
| Example 18 | 100 | Pos A | 117 | 130 | 65 | 0.90 | 18 | 55 |
| Example 19 | 100 | Pos A | 112 | 130 | 65 | 0.86 | 15 | 55 |
| Example 20 | 100 | Pos A | 107 | 130 | 65 | 0.82 | 22 | 55 |
| Example 21 | 100 | Pos A | 112 | 130 | 65 | 0.86 | 15 | 55 |
| Example 22 | 100 | Pos A | 107 | 130 | 65 | 0.82 | 22 | 55 |
| Example 23 | 100 | Pos A | 112 | 130 | 65 | 0.86 | 30 | 45 |
| Example 24 | 100 | Pos A | 112 | 130 | 65 | 0.86 | 15 | 120 |
| Example 25 | 100 | Pos A | 107 | 130 | 65 | 0.82 | 22 | 30 |
| Example 26 | 80 | Pos A | 127 | 147 | 73 | 0.87 | 10 | 35 |
| | 20 | | | | | | | |
| Example 27 | 80 | Pos A | 127 | 147 | 73 | 0.87 | 10 | 35 |
| | 20 | | | | | | | |
| Comparative | 100 | Pos A | 108 | 130 | 65 | 0.83 | 35 | 90 |
| Example 1 | | | | | | | | |
| Comparative | 100 | Pos A | 108 | 130 | 65 | 0.83 | 35 | 90 |
| Example 2 | | | | | | | | |
| Comparative | 100 | Pos A | 108 | 130 | 65 | 0.83 | 35 | 90 |
| Example 3 | | | | | | | | |
| Comparative | Pure-Ace | Pos A | 128 | 154 | 77 | 0.83 | 35 | 90 |
| Example 4 | (manufactured | | | | | | | |
| | by | | | | | | | |
| | Teijin | | | | | | | |
| | Limited.) | | | | | | | |

TABLE 3

| | | | Optical | | | | | | | | | | | |
|---|---|---|---|---|---|---|---|---|---|---|---|---|---|---|
| | Liquid crystal | | characteristics | | | | | | | | | | | |
| | composition | | of liquid | | | | | | | | | | | |
| | | Presence | crystal layer | | | | | | | Evaluation | | | | |
| | Main | of | | | Rth | | | Expres- | Product | | | Align- | | |
| | liquid | boronic | Rth | Rth | (450)/ | | | sion | (×10⁻¹² | Mounting | Oblique | ment | | |
| | crystal | acid | (450) | (550) | Rth | ΔSP | ΔSP | (1) | Pa · μm) | uneven- | light | uneven- | Adhesive- | Crack |
| | compound | monomer | (nm) | (nm) | (550) | value | (A) | ※ | ※ | ness | leakage | ness | ness | resistance |
| Example 1 | R2/R3 | Present | −79 | −90 | 0.88 | 12.2 | 8.2 | 738 | 825 | A | A | A | A | B |
| Example 2 | R1 | Present | −96 | −101 | 0.95 | 10.7 | 8.2 | 738 | 825 | A | A | A | A | B |
| Example 3 | R1 | Present | −96 | −101 | 0.95 | 11.1 | 8.2 | 738 | 990 | A | A | A | A | B |
| Example 4 | R2/R3 | Present | −79 | −90 | 0.88 | 11.7 | 7.8 | 796 | 1210 | A | A | A | A | B |
| Example 5 | R1 | Present | −96 | −101 | 0.95 | 9.9 | 7.8 | 796 | 1210 | A | A | A | A | B |
| Example 6 | R1 | Present | −96 | −101 | 0.95 | 10.0 | 7.6 | 806 | 1210 | A | A | A | A | B |
| Example 7 | R1 | Present | −96 | −101 | 0.95 | 9.8 | 7.8 | 842 | 1210 | A | A | A | A | B |
| Example 8 | R1 | Present | −96 | −101 | 0.95 | 9.8 | 7.7 | 886 | 1210 | A | A | A | A | B |
| Example 9 | R1 | Present | −96 | −101 | 0.95 | 9.9 | 7.6 | 798 | 1210 | A | A | A | A | B |
| Example 10 | R1 | Present | −96 | −101 | 0.95 | 10.7 | 8.2 | 722 | 825 | A | A | A | A | B |
| Example 11 | R1 | Present | −96 | −101 | 0.95 | 9.7 | 7.0 | 665 | 715 | A | A | A | A | C |
| Example 12 | R7 | Present | −117 | −110 | 1.06 | 9.6 | 8.2 | 738 | 825 | A | B | A | A | B |
| Example 13 | R1 | Present | −96 | −101 | 0.95 | 10.7 | 8.2 | 738 | 825 | A | B | A | A | B |
| Example 14 | R7 | Present | −117 | −110 | 1.06 | 8.8 | 7.8 | 796 | 1210 | A | B | B | A | B |
| Example 15 | R1 | None | −96 | −101 | 0.95 | 10.7 | 8.2 | 738 | 825 | A | A | A | B | B |
| Example 16 | R1 | Present | −96 | −101 | 0.95 | 12.0 | 10.3 | 948 | 1650 | B | A | A | A | A |
| Example 17 | R1 | Present | −96 | −101 | 0.95 | 8.5 | 7.5 | 705 | 990 | A | A | C | A | B |
| Example 18 | R7 | Present | −117 | −110 | 1.06 | 7.0 | 7.5 | 705 | 990 | A | B | C | A | B |
| Example 19 | R8 | Present | −80 | −95 | 0.84 | 12.1 | 8.2 | 738 | 825 | A | A | A | A | B |
| Example 20 | R8 | Present | −80 | −95 | 0.84 | 11.5 | 7.8 | 796 | 1210 | A | A | A | A | B |
| Example 21 | R1 | Present | −96 | −101 | 0.95 | 10.7 | 8.2 | 902 | 825 | A | A | A | A | A |
| Example 22 | R1 | Present | −96 | −101 | 0.95 | 9.9 | 7.8 | 1404 | 1210 | A | A | A | A | A |
| Example 23 | R1 | Present | −96 | −101 | 0.95 | 12.0 | 10.3 | 948 | 1350 | A | A | A | A | A |
| Example 24 | R1 | Present | −96 | −101 | 0.95 | 10.7 | 8.2 | 738 | 1800 | B | A | A | A | B |
| Example 25 | R1 | Present | −96 | −101 | 0.95 | 9.9 | 7.8 | 1404 | 660 | A | A | A | A | A |
| Example 26 | R2/R3 | Present | −79 | −90 | 0.88 | 9.9 | 5.3 | 2735 | 350 | A | A | B | A | A |
| Example 27 | R1 | Present | −96 | −101 | 0.95 | 8.6 | 5.3 | 2735 | 350 | A | A | C | A | A |
| Comparative | R2/R3 | Present | −79 | −90 | 0.88 | 12.8 | 9.9 | 1782 | 3150 | C | A | A | A | A |
| Example 1 | | | | | | | | | | | | | | |
| Comparative | R1 | Present | −96 | −101 | 0.95 | 11.6 | 9.9 | 1782 | 3150 | C | A | A | A | A |
| Example 2 | | | | | | | | | | | | | | |
| Comparative | R7 | Present | −117 | −110 | 1.06 | 10.7 | 9.9 | 1782 | 3150 | C | B | A | A | A |
| Example 3 | | | | | | | | | | | | | | |
| Comparative | R1 | Present | −96 | −101 | 0.95 | 11.6 | 9.9 | 0 | 3150 | C | A | A | A | A |
| Example 4 | | | | | | | | | | | | | | |

※Expression (1): Nw × ΔSP (A)
※Product: A product of a photoelastic constant (unit: Pa) and a thickness (unit: μm)

As shown in Table 2 and Table 3, it was found that mounting unevenness occurred in a case where a retardation film in which the photoelastic constant of the support was more than 30×10⁻¹² Pa was used (Comparative Examples 1 to 4).

On the other hand, it was found that in a case where a retardation film in which the photoelastic constant of the support was 30×10⁻¹² Pa or less or the product of the photoelastic constant and the thickness was 2,000×10⁻¹² Pa·μm or less was used, the occurrence of mounting unevenness could be suppressed (Examples 1 to 27).

In particular, from the results of Examples 1 to 20 (particularly, the comparison results between Examples 14, 17, and 18 and the other examples), it was found that in a case where the ΔSP value was 8.8 or more, the alignment unevenness was suppressed, and in a case where the ΔSP value was 9.5 or more, the alignment unevenness was further suppressed.

In addition, from the comparison between Example 1 and Example 12, it was found that in a case where the retardation in the thickness direction in the liquid crystal layer exhibited reverse wavelength dispersibility, oblique light leakage was suppressed.

In addition, from the comparison between Example 2 and Example 13, it was found that in a case where the support was a positive A-plate, oblique light leakage was suppressed.

In addition, from the comparison between Example 1 and Example 15, it was found that in a case where the liquid crystal composition contained a boronic acid monomer having a polymerizable group and a boronic acid group represented by Formula (B), the adhesiveness between the support and the liquid crystal layer was improved.

In addition, from the comparison between Example 2 and Example 16, it was found that in a case where the photoelastic constant of the support was 25×10⁻¹² Pa or less, the occurrence of mounting unevenness was further suppressed.

In addition, from the comparison between Examples 2, 11, and 21 to 25, it was found that the polymer contained in the polymer film (support) exhibits excellent crack resistance in a case where the product (Nw×ΔSP(A)) of Nw and ΔSP(A) in Expression (1) was 700 or more, and the crack resistance was more excellent in a case where the product was 900 or more.

What is claimed is:

1. A retardation film comprising:
a support having an in-plane retardation exhibiting reverse wavelength dispersibility; and
a liquid crystal layer that is directly laminated on the support,
wherein the support is a polymer film that has been subjected to a stretching treatment in at least one in-plane direction, the liquid crystal layer is a positive C-plate obtained by immobilizing an alignment state of a liquid crystal composition containing a liquid crystal compound, and a photoelastic constant of the support is 30×10⁻¹² Pa or less.

2. The retardation film according to claim 1,
wherein a difference between a solubility parameter of a polymer contained in the polymer film and a solubility parameter of a liquid crystal compound having a highest content among liquid crystal compounds contained in the liquid crystal composition is 8.8 or more.

3. The retardation film according to claim 1,
wherein a polymer contained in the polymer film is polycarbonate or polyester.

4. The retardation film according to claim 1,
wherein the photoelastic constant of the support is 25×10⁻¹² Pa or less.

5. The retardation film according to claim 1,
wherein a difference between a solubility parameter of a polymer contained in the polymer film and a solubility parameter of a liquid crystal compound having a highest content among liquid crystal compounds contained in the liquid crystal composition is 9.5 or more.

6. The retardation film according to claim 1,
wherein the support is a positive A-plate.

7. The retardation film according to claim 1,
wherein a thickness direction retardation of the liquid crystal layer exhibits reverse wavelength dispersibility.

8. The retardation film according to claim 1,
wherein the liquid crystal composition further contains a boronic acid monomer having a polymerizable group and a boronic acid group represented by Formula (B), 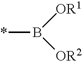
in Formula (B)
* represents a bonding position,
R¹ and R² each independently represent a hydrogen atom, an aliphatic hydrocarbon group which may have a substituent, an aryl group which may have a substituent, or a heterocyclic group which may have a substituent, and R¹ and R² may be linked to each other to form a ring.

9. The retardation film according to claim 1,
wherein a polymer contained in the polymer film satisfies Expression (1),
Nw×ΔSP(A)≥700 (1)
in Expression (1),
Nw represents a weight average degree of polymerization of the polymer contained in the polymer film, and
ΔSP(A) represents a difference between a solubility parameter of the polymer contained in the polymer film and a solubility parameter of acetone.

10. A retardation film comprising:
a support having an in-plane retardation exhibiting reverse wavelength dispersibility; and
a liquid crystal layer that is directly laminated on the support,
wherein the support is a polymer film that has been subjected to a stretching treatment in at least one in-plane direction, the liquid crystal layer is a positive C-plate obtained by immobilizing an alignment state of a liquid crystal composition containing a liquid crystal compound, and
a product of a photoelastic constant (unit: Pa) and a thickness (unit: μm) of the support is 2,000×10⁻¹² Pa·μm or less.

11. The retardation film according to claim 1,
wherein a polymer contained in the polymer film is polycarbonate or polyester and satisfies Expression (1),
Nw×ΔSP(A)≥700 (1)
in Expression (1),
Nw represents a weight average degree of polymerization of the polymer contained in the polymer film, and
ΔSP(A) represents a difference between a solubility parameter of the polymer contained in the polymer film and a solubility parameter of acetone.

12. The retardation film according to claim 10,
wherein a polymer contained in the polymer film is polycarbonate or polyester and satisfies Expression (1),
Nw×ΔSP(A)≥700 (1)
in Expression (1),
Nw represents a weight average degree of polymerization of the polymer contained in the polymer film, and
ΔSP(A) represents a difference between a solubility parameter of the polymer contained in the polymer film and a solubility parameter of acetone.

13. A polarizing plate comprising:
the retardation film according to claim 1; and
a polarizer
wherein the liquid crystal layer included in the retardation film and the polarizer are disposed so as to contact with each other or disposed via a pressure-sensitive adhesive layer.

14. A polarizing plate comprising:
the retardation film according to claim 11; and
a polarizer
wherein the liquid crystal layer included in the retardation film and the polarizer are disposed so as to contact with each other or disposed via a pressure-sensitive adhesive layer.

15. A polarizing plate comprising:
the retardation film according to claim 12; and
a polarizer
wherein the liquid crystal layer included in the retardation film and the polarizer are disposed so as to contact with each other or disposed via a pressure-sensitive adhesive layer.

16. The polarizing plate according to claim 13,
wherein an absorption axis of the polarizer and a slow axis of the support of the retardation film are orthogonal or parallel to each other.

17. The polarizing plate according to claim 13,
wherein the absorption axis of the polarizer and the slow axis of the support of the retardation film are parallel to each other.

18. An image display device comprising:
the polarizing plate according to claim 13.

19. An image display device comprising:
the polarizing plate according to claim 14.

20. An image display device comprising:
the polarizing plate according to claim 15.
